(19) United States
(12) Patent Application Publication
(10) Pub. No.: US 2015/0035024 A1
(43) Pub. Date: Feb. 5, 2015

(54) TRANSISTOR AND METHOD OF MANUFACTURING THE SAME

(71) Applicant: Dae-Shik KIM, Hwaseong-si (KR)

(72) Inventor: Dae-Shik KIM, Hwaseong-si (KR)

(21) Appl. No.: 14/265,309

(22) Filed: Apr. 29, 2014

(30) Foreign Application Priority Data
Aug. 2, 2013 (KR) 10-2013-0092040

(51) Int. Cl. H01L 29/78; H01L 29/66

(52) U.S. Cl. CPC H01L 29/78; H01L 29/66477
USPC 257/288; 438/301

(57) ABSTRACT

A transistor includes a substrate, a gate structure and impurity regions. The substrate is divided into a field region and an active region by an isolation layer pattern. The field region has the isolation layer pattern thereon, and the active region has no isolation layer pattern thereon. The gate structure includes a central portion and an edge portion. The central portion is on a middle portion of the active region along a first direction and has a first width in a second direction substantially perpendicular to the first direction. The edge portion is on at least one end portion of the active region in the first direction and connected to the central portion and has a second width smaller than the first width in the second direction. The impurity regions are at upper portions of the active region adjacent to both end portions of the gate structure in the second direction.

### CROSS-REFERENCE TO RELATED APPLICATION

This application claims priority under 35 USC §119 to Korean Patent Application No. 10-2013-0092040, filed on Aug. 2, 2013 in the Korean Intellectual Property Office (KIPO), the contents of which are herein incorporated by reference in their entirety.

### BACKGROUND

1. Field

Example embodiments relate to a transistor and a method of manufacturing the same.

2. Description of the Related Art

A transistor may be formed by several processing steps such as forming an isolation layer pattern on a substrate to divide the substrate into an active region and a field region, forming a gate structure on the substrate, and forming impurity regions at upper portions of the active region adjacent to the gate structure. Various efforts have been made to reduce a so-called “hump” phenomenon and/or Hot Electron Induced Punch-through (HEIP) phenomenon that may occur in the transistor to improve electrical characteristics of the transistor.

### SUMMARY

Example embodiments provide a transistor having good electrical characteristics.

Example embodiments provide a method of manufacturing a transistor having good electrical characteristics.

According to example embodiments, there is provided a transistor. The transistor includes a substrate, a gate structure and impurity regions. The substrate is divided into a field region and an active region by an isolation layer pattern. The field region has the isolation layer pattern thereon, and the active region has no isolation layer pattern thereon. The gate structure includes a central portion and an edge portion. The central portion is on a middle portion of the active region along a first direction and has a first width in a second direction substantially perpendicular to the first direction. The edge portion is on at least one end portion of the active region in the first direction and connected to the central portion and has a second width smaller than the first width in the second direction. The impurity regions are at upper portions of the active region adjacent to both end portions of the gate structure in the second direction.

In example embodiments, the edge portion of the gate structure may be formed on both end portions of the active region in the first direction.

In example embodiments, the edge portion of the gate structure may be formed on a portion of the isolation layer pattern adjacent to the at least one end portion of the active region in the first direction.

In example embodiments, each impurity region may extend in the first direction in the active region.

In example embodiments, each impurity region may extend in the first direction with a uniform width in the second direction.

In example embodiments, each impurity region may include a first impurity region having a first impurity concentration and a second impurity region having a second impurity concentration higher than the first impurity concentration.

In example embodiments, the second impurity region may be formed within the first impurity region in a top view.

According to example embodiments, there is provided a method of manufacturing a transistor. In the method, an isolation layer pattern is formed on the substrate to divide the substrate into an active region and a field region. A gate structure is formed to include a central portion and an edge portion. The central portion is on a middle portion of the active region along a first direction and has a first width in a second direction substantially perpendicular to the first direction. The edge portion is on at least one end portion of the active region in the first direction and connected to the central portion and has a second width smaller than the first width in the second direction. The impurity regions are formed at upper portions of the active region adjacent to both end portions of the gate structure in the second direction.

In example embodiments, when the impurity regions are formed, an ion implantation process may be performed using an ion implantation mask having openings, each of the openings extending in the first direction adjacent to the end portions of the gate structure in the second direction.

In example embodiments, when the impurity regions are formed, an ion implantation process may be performed using an ion implantation mask, the ion implantation mask having a width equal to or greater than the first width of the gate structure in the second direction and covering the edge portion of the gate structure and a portion of the active region adjacent thereto.

In example embodiments, the edge portion of the gate structure may be formed on both end portions of the active region in the first direction.

In example embodiments, the edge portion of the gate structure may be formed on a portion of the isolation layer pattern adjacent to the at least one end portion of the active region in the first direction.

In example embodiments, each impurity region may be formed to extend in the first direction with a uniform width in the second direction in the active region.

In example embodiments, each impurity region may be formed to include a first impurity region having a first impurity concentration and a second impurity region having a second impurity concentration higher than the first impurity concentration.

In example embodiments, when the gate structure is formed, a gate insulation layer, a gate electrode layer and a mask may be sequentially formed on the substrate and the isolation layer pattern. The gate electrode layer and the gate insulation layer may be sequentially patterned using the mask as an etching mask.

According to example embodiments, the gate structure may be formed to include the central portion, which may have a larger width in the second direction on the middle portion of the active region in the first direction, and the edge portion, which may have a smaller width in the second direction on at least one end portion of the active region in the first direction to be connected to the central portion. In addition, the gate structure may be formed only on the middle portion of the active region. Thus transistor including the gate structure may be limitedly formed only at the middle portion of the active region in the first direction, so that a threshold voltage variation may be reduced, and a hump phenomenon and/or HEIP may not be generated in the transistor.

The gate structure of the transistor may be formed to include the central portion formed on a middle portion of the active region and the edge portion formed on an edge portion of the active region to have a smaller width than that of the central portion. Thus, source and drain regions of the transistor may not be adjacent to the edge portion of the gate structure. Alternatively, the gate structure may be formed on the active region to have an isolated shape, so that the gate structure may be spaced apart from the source and drain regions. As a result, the transistor may be substantially formed on the confined middle portion of the active region, and thus a threshold voltage variation causing hump and HEIP may be not generated in the interface between the active region and the field region. That is, electrical characteristics of the transistor may be not deteriorated.

### BRIEF DESCRIPTION OF THE DRAWINGS

Example embodiments will be more clearly understood from the following detailed description taken in conjunction with the accompanying drawings. FIGS. 1 to 12 represent non-limiting, example embodiments as described herein.

FIG. 1 is a plan view illustrating a transistor in accordance with example embodiments, and FIGS. 2 and 3 are cross-sectional views illustrating the transistor;

FIGS. 4, 5, 7 and 10 are cross-sectional views illustrating stages of a method of manufacturing a transistor in accordance with example embodiments, and FIGS. 6, 8 and 9 are plan views illustrating stages of a method of manufacturing the transistor;

FIG. 11 is a plan view illustrating a transistor in accordance with other example embodiments, and FIG. 12 is a cross-sectional view illustrating the transistor;

FIGS. 13 to 15 are plan views illustrating stages of a method of manufacturing a transistor in accordance with other example embodiments;

FIGS. 16 and 18 are plan views illustrating a transistor in accordance with still other example embodiments, and FIGS. 17 and 19 are cross-sectional views illustrating the transistor;

FIGS. 20 to 22 are plan views illustrating stages of a method of manufacturing a transistor in accordance with still other example embodiments; and

FIGS. 23, 25 to 29, 32 and 36 to 56 are cross-sectional views illustrating stages of a method of manufacturing a semiconductor device in accordance with example embodiments, and FIGS. 24, 30, 31 and 33 to 35 are plan views illustrating stages of a method of manufacturing the transistor.

FIG. 57 is a schematic block diagram illustrating an example of information processing systems including a semiconductor device according to example embodiments of the present disclosure.

### DESCRIPTION OF EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

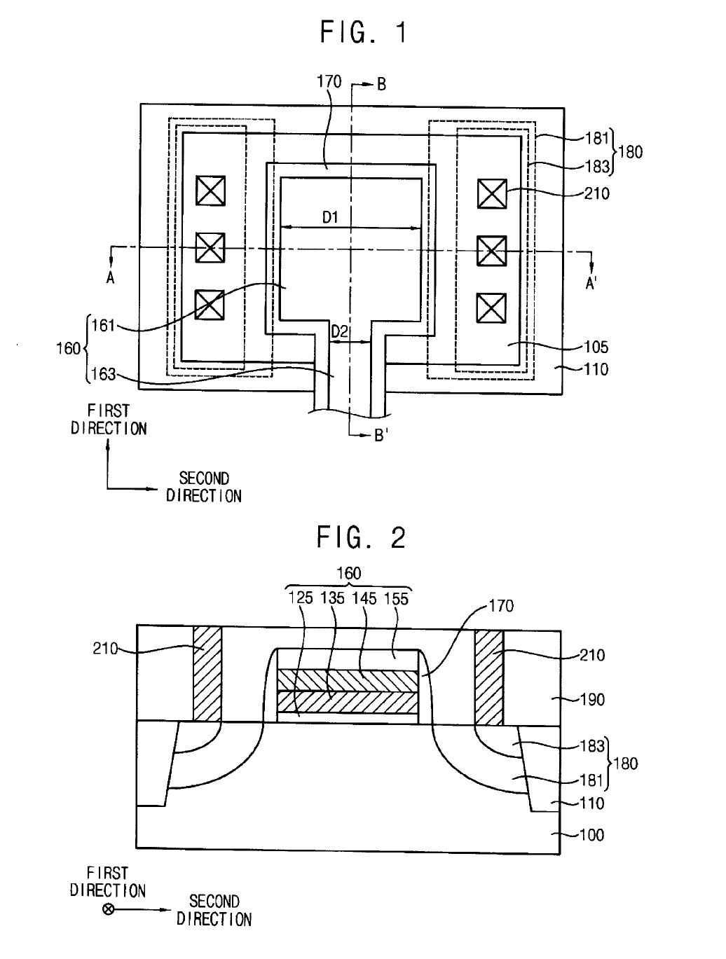

FIG. 1 is a plan view illustrating a transistor in accordance with example embodiments, and FIGS. 2 and 3 are cross-sectional views illustrating the transistor. Particularly, FIG. 2 is a cross-sectional view cut along line A-A′ of FIG. 1, and FIG. 3 is a cross-sectional view cut along line B-B′ of FIG. 1. The line A-A′ extends in a second direction substantially parallel to a top surface of a substrate, and line B-B′ extends in a first direction substantially parallel to the top surface of the substrate and substantially perpendicular to the second direction.

Referring to FIGS. 1 to 3, the transistor may include a substrate 100, a gate structure 160 and impurity regions 180.

An isolation layer pattern 110 may be formed on the substrate 100, so that a portion of the substrate 100 on which the isolation layer pattern 110 is formed may be defined as a field region, and a portion of the substrate 100 on which the isolation layer pattern 110 is not formed may be defined as an active region 105. A portion of the substrate 100, on which the isolation layer pattern 110 is formed, may be defined as the field region, and a portion of the substrate 100, on which the isolation layer pattern 110 is not formed, may be defined as the active region 105. The substrate 100 may be a silicon substrate, a germanium substrate, a silicon-germanium substrate, a silicon-on-insulator (SOI) substrate, a germanium-on-insulator (GOI) substrate, etc. The isolation layer pattern 110 may include an oxide, e.g., silicon oxide.

The gate structure 160 may include a central portion 161 on a middle portion of the active region 105 in the first direction, and an edge portion 163 on one end portion of the active region 105 in the first direction, which may be connected to the central portion 161.

The central portion 161 of the gate structure 160 may have a first width D1 in the second direction, and the edge portion 163 of the gate structure 160 may have a second width D2 in the second direction. The second width D2 may be smaller than the first width D1. In example embodiments, the edge portion 163 of the gate structure 160 may also be formed on a portion of the isolation layer pattern 110 adjacent to the end portion of the active region 105 in the first direction.

In example embodiments, the gate structure 160 may include a gate insulation layer pattern 125, a first gate electrode 135, a second gate electrode 145 and a mask 155 sequentially stacked on the substrate 100. Alternatively, the gate structure 160 may not include the second gate electrode 145 but include the first gate electrode 135 only.

The gate insulation layer pattern 125 may include an oxide, e.g., silicon oxide. The first and second gate electrodes 135 and 145 may include a conductive material, e.g. a metal such as tungsten (W), etc., and/or polysilicon doped with impurities. The mask 155 may include a nitride, e.g., silicon nitride.

A sidewall of the gate structure 160 may be surrounded by a spacer 170, and the spacer 170 may include a nitride, e.g. silicon nitride.

The impurity regions 180 may be formed at upper portions of the active region 105 adjacent to end portions of the gate structure 160 in the second direction. Each impurity region 180 may extend in the first direction and have a substantially uniform width in the second direction. Accordingly, the impurity regions 180 may be adjacent to the central portion 161 of the gate structure 160 but may not be adjacent to the edge portion 163 of the gate structure 160.

In example embodiments, each impurity region 180 may include a first impurity region 181 having a first impurity concentration and a second impurity region 183 having a second impurity concentration higher than the first impurity concentration. The second impurity region 183 may be formed in the first impurity region 181 to be surrounded by the first impurity region 181 in plan view. In this case, the gate structure 160 and the impurity regions 180 may form a high voltage transistor, and the impurity regions 180 may serve as source and drain regions of the high voltage transistor. The first and second impurity regions 181 and 183 may include, for example, n-type impurities such as phosphorus, arsenic, etc., or p-type impurities such as boron, gallium, etc.

Alternatively, each impurity region 180 may include only the first impurity region 181 and need not include the second impurity region 183. In this case, the gate structure 160 and the impurity regions 180 may form a low voltage transistor, and the impurity regions 180 may serve as source and drain regions of the low voltage transistor.

The impurity regions 180, the gate structure 160 and the spacer 170 may be covered by an insulating interlayer 190 on the substrate 100. The insulating interlayer 190 may include an oxide, e.g., boro phospho silicate glass (BPSG), undoped silicate glass (USG) and spin on glass (SOG), etc.

A contact plug 210 may be formed though the insulating interlayer 190 to contact a top surface of each impurity region 180. The contact plug 210 may include a conductive material, e.g., a metal and/or polysilicon doped with impurities.

As illustrated above, the gate structure 160 may include the central portion 161, which may be formed on the middle portion of the active region 105 in the first direction and have the first width D1, and an edge portion 163, which may be formed on the end portion of the active region 105 in the first direction to be connected to the central portion 161 and have the second width D2 smaller than the first width D1. Thus, the transistor including the gate structure 160 may be formed only at the middle portion of the active region 105 in the first direction.

That is, the impurity regions 180 may extend in the first direction in the active region 105 with a substantially uniform width in the second direction, while the gate structure 160 may have a width different on the middle portion than on end portions of the active region 105. Thus, the central portion 161 of the gate structure 160 may be adjacent to the impurity regions 180, while the edge portion 163 of the gate structure 160 may be separated or spaced apart from the impurity regions 180. In some embodiments, substantially all of the central portion 161 of the gate structure 160 may be adjacent to the impurity regions 180, while most of the edge portion 163 of the gate structure 160 may be spaced apart from the impurity regions 180. As a result, a channel of the transistor may not be formed at an interface between the field region and the active region 105 in the first direction. As a result, a threshold voltage variation may be reduced and a hump phenomenon and/or HEIP may not be generated in the transistor.

In some embodiments, as shown in FIG. 2, a distance between one end of the gate structure 160 to an opposing end of the isolation layer pattern 110 is substantially the same as a distance between an opposite end of the gate structure 160 and an opposing end of the isolation layer pattern 110.

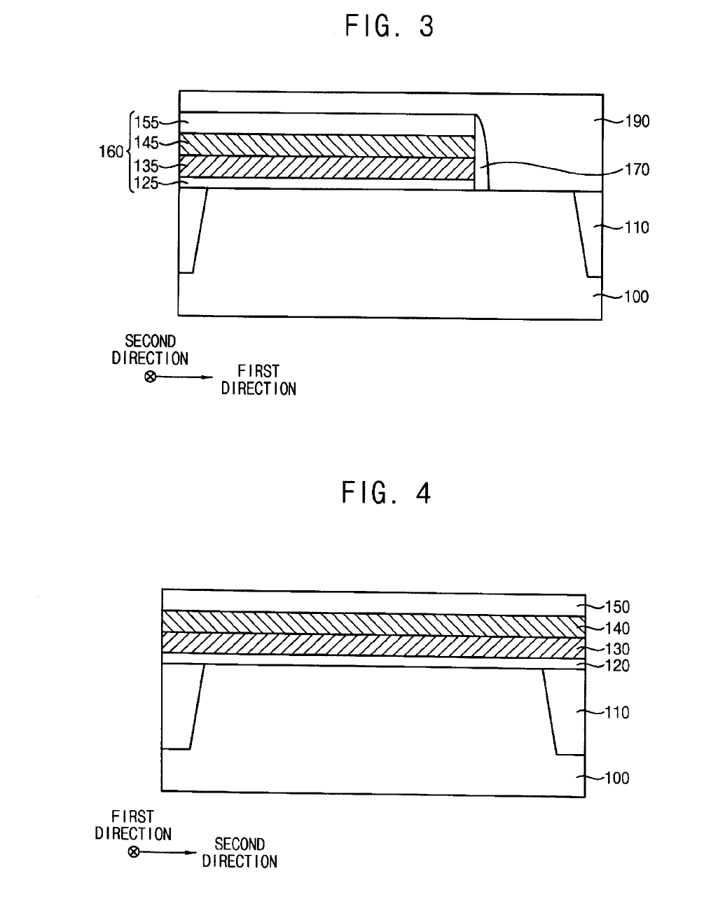

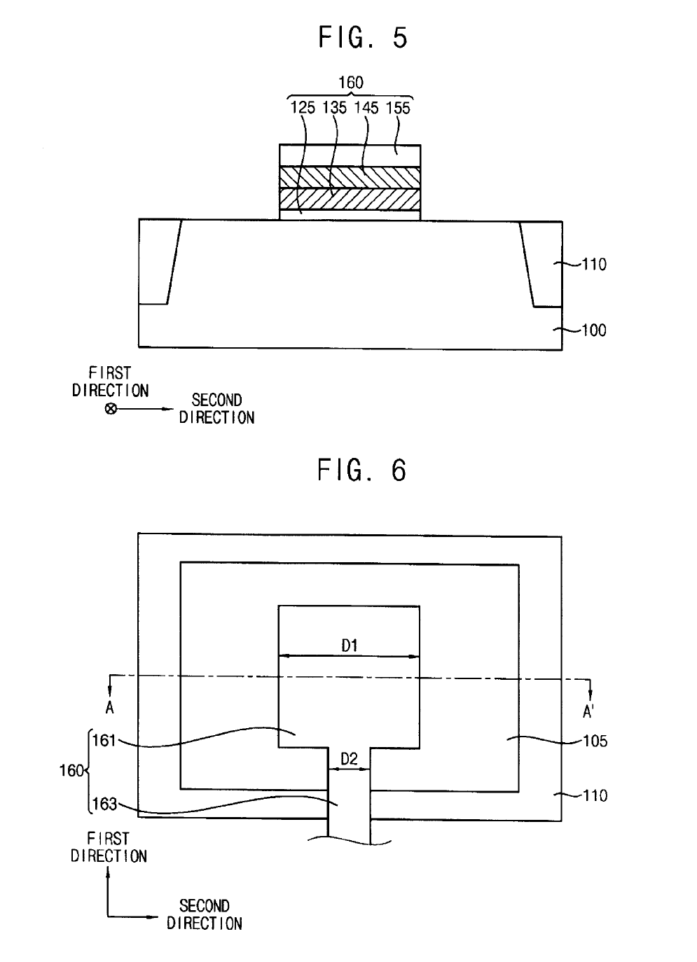

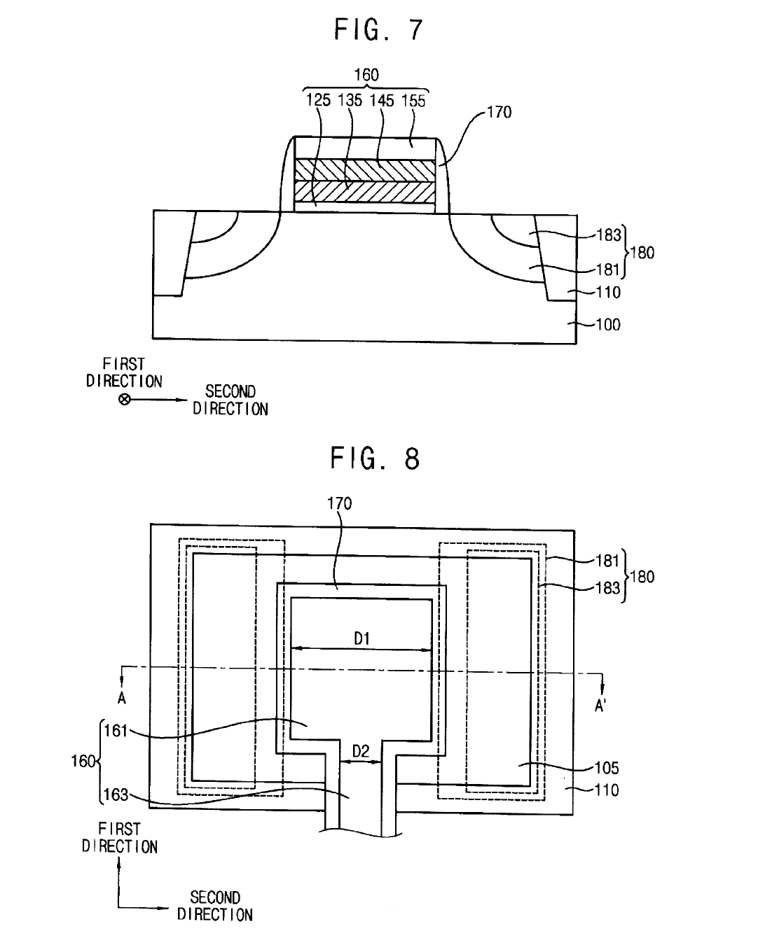

FIGS. 4, 5, 7 and 10 are cross-sectional views illustrating stages of a method of manufacturing a transistor in accordance with example embodiments, and FIGS. 6, 8 and 9 are plan views illustrating stages of a method of manufacturing the transistor. Particularly, FIG. 5 is a cross-sectional view cut along line A-A′ of FIG. 6, and FIG. 7 is a cross-sectional view cut along line A-A′ of FIG. 8.

Referring to FIG. 4, an isolation layer pattern 110 may be formed on the substrate 100 to divide the substrate 100 into an active region 105 and a field region, and a gate insulation layer 120, a first gate electrode layer 130, a second gate electrode layer 140 and a mask layer 150 may be sequentially formed on the substrate 100 and the isolation layer pattern 110.

The substrate 100 may be a silicon substrate, a germanium substrate, a silicon-germanium substrate, a silicon-on-insulator (SOI) substrate, a germanium-on-insulator (GOI) substrate, etc.

The isolation layer pattern 110 may be formed by forming a trench (not shown) at an upper portion of the substrate 100, forming an isolation layer on the substrate 100 to sufficiently fill the trench, and planarizing an upper portion of the isolation layer until a top surface of the substrate 100 may be exposed. The isolation layer pattern 110 may be formed to include an oxide, e.g., silicon oxide.

The gate insulation layer 120 may include an oxide, e.g., silicon oxide. The first and second gate electrode layers 130 and 140 may include a conductive material, e.g., a metal such as tungsten (W), etc., and/or polysilicon doped with impurities. The mask layer 150 may be formed to include a nitride, for example, silicon nitride.

Referring to FIGS. 5 and 6, the mask layer 150 may be etched to form a mask 155, and the second gate electrode layer 140, the first gate electrode layer 130 and the gate insulation layer 120 may be patterned sequentially, using the mask 155 as an etching mask. Accordingly, a gate structure 160 including a gate insulation layer pattern 125, a first gate electrode 135, a second gate electrode 145 and the mask 155 sequentially stacked on the substrate 100 and the isolation layer pattern 110 may be formed.

According to the patterning process, a portion of the gate structure 160 on a middle portion of the active region 105 in the first direction may have a first width D1 in the second direction, and a portion of the gate structure 160 on one end portion of the active region 105 in the first direction may have a second width D2 in the second direction. That is, the gate structure 160 may include a central portion 161 on the middle portion of the active region 105 in the first direction, and an edge portion 163 on the end portion of the active region 105 in the first direction and being connected to the central portion 161. The central portion 161 has the first width D1 and the edge portion 163 has the second width D2. In example embodiments, the edge portion 163 of the gate structure 160 may be also formed on a portion of the isolation layer pattern 110 adjacent to the end portion of the active region 105 in the first direction. The second width D2 may be smaller than the first width D1.

Referring to FIGS. 7 and 8, a spacer 170 may be formed on a sidewall of the gate structure 160. Thereafter, impurity regions 180 may be formed at upper portions of the active region 105 adjacent to end portions of the gate structure 160 in the second direction. In example embodiments, the impurity regions 180 may extend in the first direction with a substantially uniform width in the second direction in the active region 105. Thus, the impurity regions 180 may be formed adjacent to the central portion 161 of the gate structure 160 but not adjacent to the edge portion 163 of the gate structure 160.

In example embodiments, the spacer 170 may be formed by forming a spacer layer on the substrate 100 to cover the gate structure 160, and anisotropically etching the spacer layer. Accordingly, the spacer 170 may be formed to surround the sidewall of the gate structure 160. The spacer layer may include a nitride, for example, silicon nitride.

The impurity regions 180 may be formed by performing an ion implantation process using an ion implantation mask (not shown) having openings (not shown), which may extend in the first direction adjacent to the end portions of the gate structure 160 in the second direction.

In example embodiments, the impurity regions 180 may be formed to include a first impurity region 181 having a first impurity concentration and a second impurity region 183 having a second impurity concentration higher than the first impurity concentration. The first impurity region 181 may be formed using a first mask (not shown) having first openings (not shown) with a third width which is substantially uniform in the second direction, and the second impurity region 183 may be formed using a second mask (not shown) having second openings (not shown) with a fourth width which is substantially uniform in the second direction and smaller than the third width. Accordingly, the second impurity region 183 may be formed in the first impurity region 181 in a top view.

Alternatively, as shown in FIG. 9, a mask 185 having a width substantially equal to or greater than the first width D1 of the gate structure 160 in the second direction and covering the edge portion 163 of the gate structure 160 and a portion of the active region 105 adjacent thereto may be used as an ion implantation mask to perform an ion implantation process for forming the impurity regions 180. In this case, the second impurity region 183 may not be formed, so that the impurity regions 180 may include only the first impurity region 181.

The impurity regions 180 and the gate structure 160 may form a transistor, and the impurity regions 180 may serve as source and drain regions of the transistor. In example embodiments, when the impurity regions 180 are formed to include the first and second impurity regions 181 and 183, a high voltage transistor including the impurity regions 180 may be formed. Alternatively, when the impurity regions 180 includes only the first impurity region 181, a low voltage transistor including the impurity regions 180 may be formed.

The first and second impurity regions 181 and 183 may be formed to include, for example, n-type impurities such as phosphorus, arsenic, etc., or p-type impurities such as boron, gallium, etc.

In some embodiments, after the impurity regions 180 may be formed, the gate structure 160 may be formed.

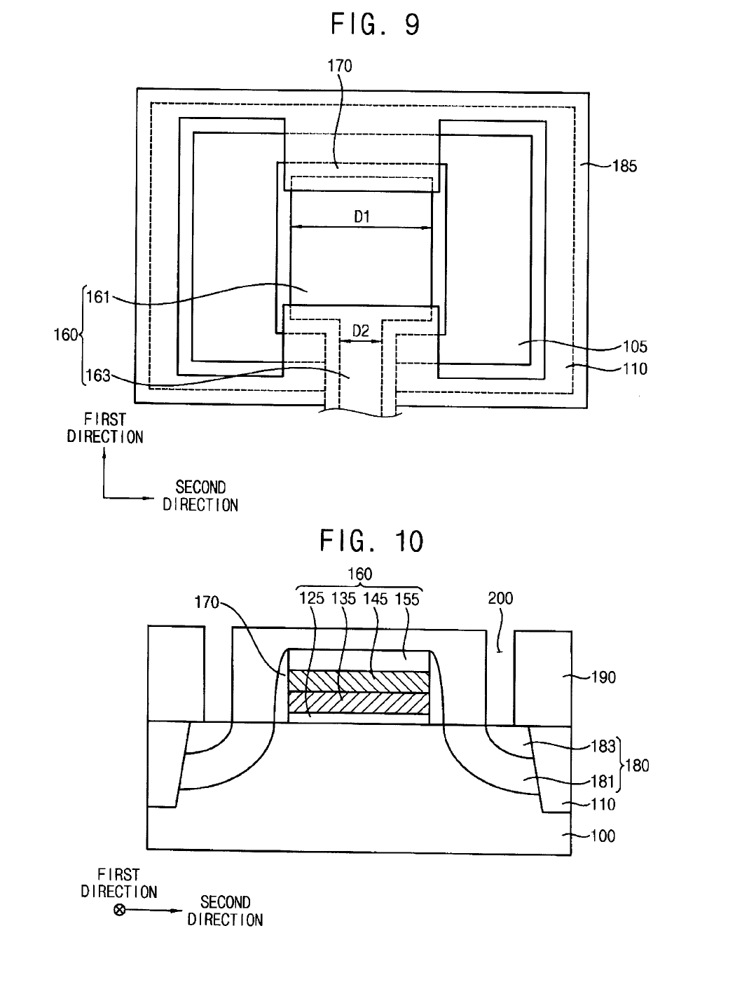

Referring to FIG. 10, an insulating interlayer 190 may be formed on the substrate 100 to cover the gate structure 160 and the spacer 170, and a contact hole 200 partially exposing a top surface of each impurity region 180 may be formed through the insulating interlayer 190.

The insulating interlayer 190 may include an oxide, e.g., boro phospho silicate glass (BPSG), undoped silicate glass (USG) and spin on glass (SOG), etc.

The contact hole 200 may be formed by forming a hardmask (not shown) on the insulating interlayer 190, and etching the insulating interlayer 190 using the hardmask as an etching mask. In example embodiments, when a high voltage transistor is formed, the contact hole 200 may be formed to expose a top surface of each second impurity region 183, and when a low voltage transistor is formed, the contact hole 200 may be formed to expose a top surface of each first impurity region 181.

Referring to FIGS. 1 to 3 again, a conductive layer may be formed on the substrate 100 and the insulating interlayer 190 to sufficiently fill the contact hole 200, and an upper portion of the conductive layer may be planarized until a top surface of the insulating interlayer 190 may be exposed to form a contact plug 210. The conductive layer may include a conductive material such as metal and/or polysilicon doped with impurities. In example embodiments, when a high voltage transistor is formed, the contact plug 210 may contact the top surface of the second impurity region 183, and when a low voltage transistor is formed, the contact plug 210 may contact the top surface of the first impurity region 181.

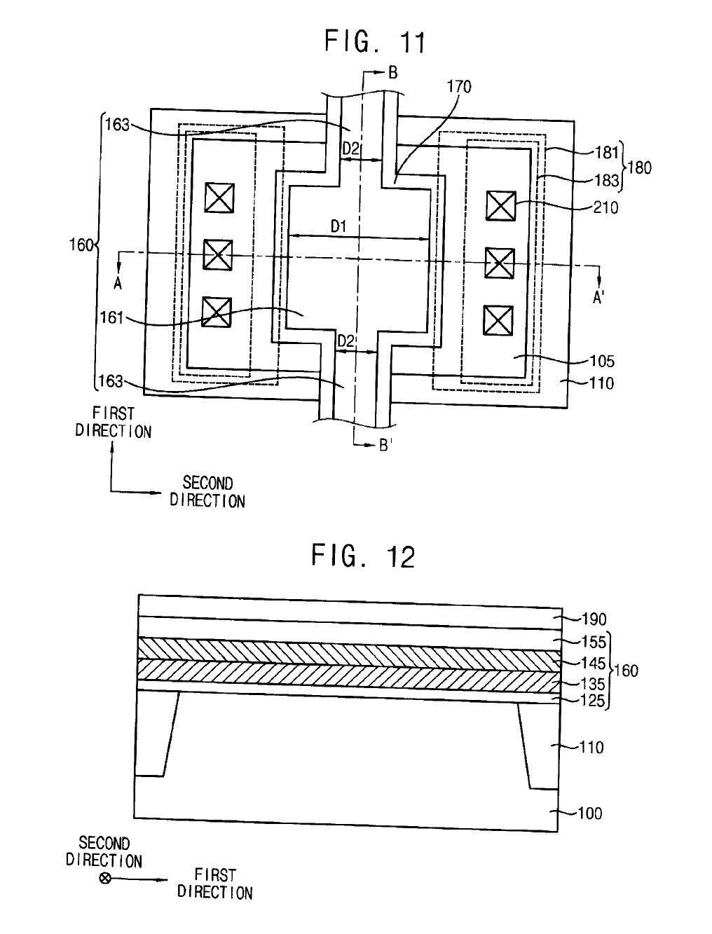

FIG. 11 is a plan view illustrating a transistor in accordance with other example embodiments, and FIG. 12 is a cross-sectional view illustrating the transistor shown in FIG. 11. Particularly, FIG. 12 is a cross-sectional view cut along line B-B′ of FIG. 11. The line B-B′ extends in a first direction. A cross-sectional view cut along line A-A′ of FIG. 11 is substantially the same as that of FIG. 2. The transistor of FIGS. 11 and 12 may be substantially the same as or similar to that illustrated with reference to FIGS. 1 to 3 except for an edge portion 163 of the gate structure 160. Thus, like reference numerals refer to like elements, and detailed explanations thereabout may be omitted herein.

Referring to FIGS. 11, 12 and 2, the transistor may include a substrate 100, a gate structure 160 and impurity regions 180.

The substrate 100 may be divided into an active region 105 and a field region by an isolation layer pattern 110 formed on the substrate 100.

The gate structure 160 may include a central portion 161 arranged substantially on a middle portion of the active region 105 in the first direction, and edge portions 163 arranged on both end portions of the active region 105 in the first direction, which may be connected to the central portion 161. The central portion 161 of the gate structure 160 may have a first width D1 in the second direction, and the edge portions 163 of the gate structure 160 may have a second width D2 in the second direction. The second width D2 may be smaller than the first width D1. In example embodiments, the edge portions 163 of the gate structure 160 may be formed on portions of the isolation layer pattern 110 adjacent to end portions of the active region 105 in the first direction, and thus the gate structure 160 may extend in the first direction.

The gate structure 160 may include a gate insulation layer pattern 125, a first gate electrode 135, a second gate electrode 145 and a mask 155 sequentially stacked on the substrate 100. A sidewall of the gate structure 160 may be substantially surrounded (or covered) by a spacer 170.

The impurity regions 180 may be formed at upper portions of the active region 105 adjacent to end portions of the gate structure 160 in the second direction, respectively. In example embodiments, each impurity region 180 may extend in the first direction with a substantially uniform width in the second direction. Accordingly, the impurity regions 180 may be adjacent to the central portion 161 of the gate structure 160 but are spaced apart from the edge portions 163 of the gate structure 160.

In example embodiments, the impurity regions 180 may include first and second impurity regions 181 and 183. Alternatively, the impurity regions 180 may not include the second impurity region 183 and need not include only the first impurity region 18. When the impurity regions 180 include the first and second impurity regions 181 and 183, the impurity regions 180 and the gate structure 160 may form a high voltage transistor. When impurity regions 180 may include first impurity region 181 only, the impurity regions 180 and the gate structure 160 may form a low voltage transistor. The impurity regions 180 may serve as source and drain regions of the transistors.

The impurity regions 180, the gate structure 160 and the spacer 170 may be covered by an insulating interlayer 190. A contact plug 210 may be formed through the insulating interlayer to contact a top surface of each impurity regions 180.

As illustrated above, the gate structure 160 may include the central portion 161 on the substantially middle portion of the active region 105 in the first direction with the first width D1, and the edge portions 163 formed on both end portions of the active region 105 in the first direction, which may be connected to the central portion 161 and have the second width D2 smaller than the first width D1 in the second direction. Thus, the transistor including the gate structure 160 may be formed only at the middle portion of the active region 105 in the first direction.

That is, the edge portion 163 of the gate structure 160 may not be adjacent to the impurity regions 180 unlike the central portion 161 of the gate structure 160, and thus a channel of the transistor may not be formed at an interface between the field region and the active region 105 in the first direction, so that a threshold voltage variation may be reduced, and a hump phenomenon and/or HEIP may not be generated in the transistor.

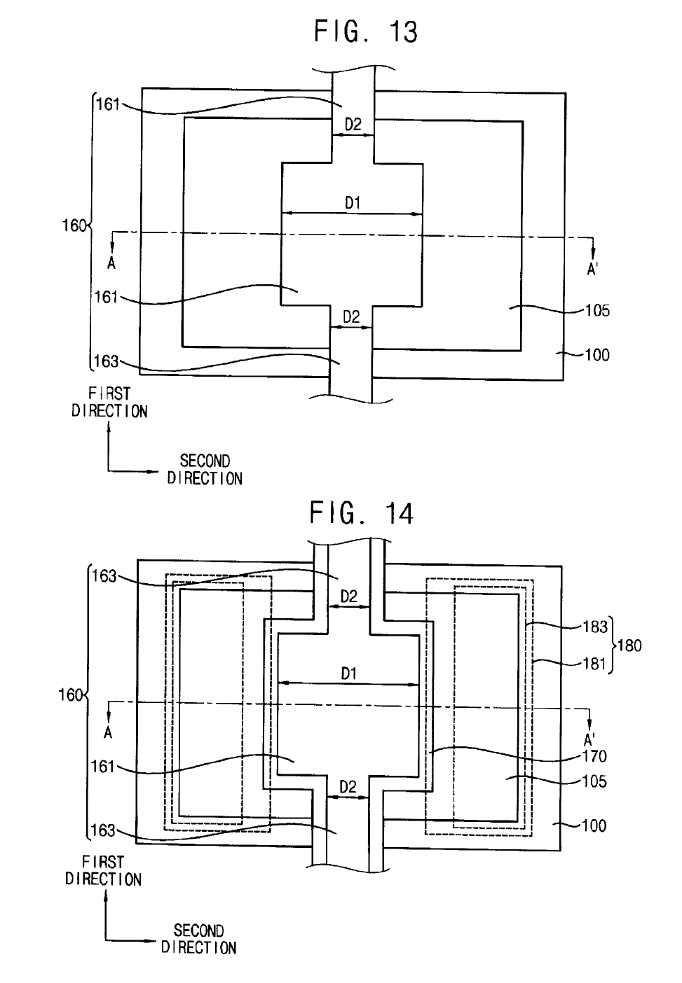

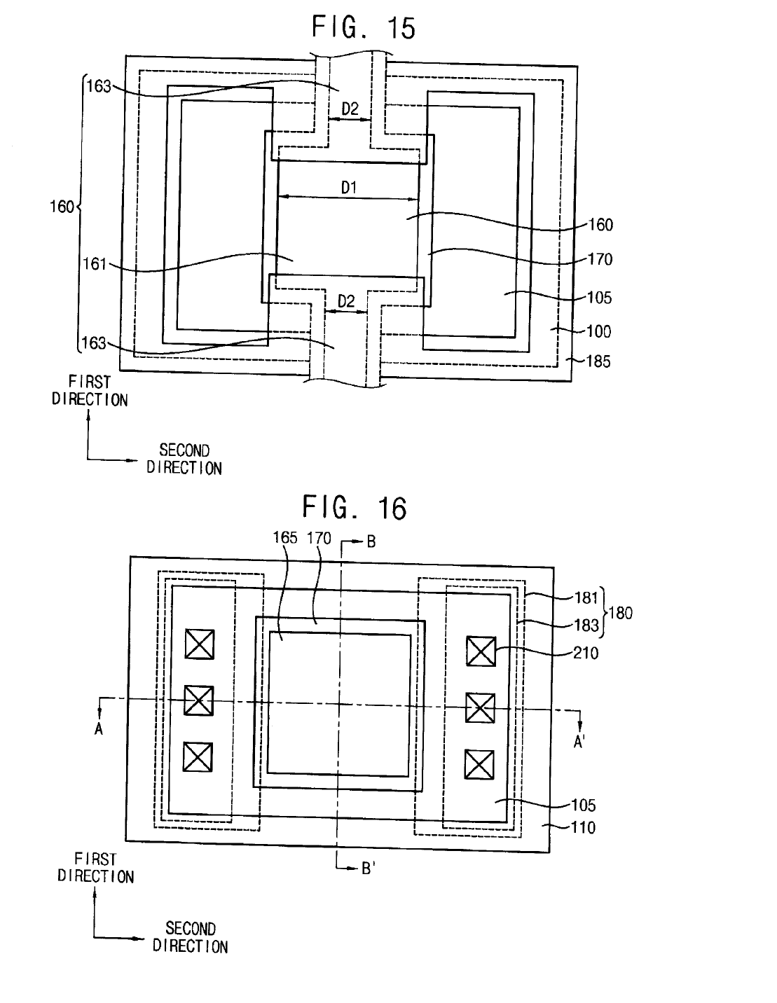

FIGS. 13 to 15 are plan views illustrating stages of a method of manufacturing a transistor in accordance with other example embodiments. A cross-sectional view cut along line A-A′ of FIG. 13 is substantially the same as that of FIG. 5, and a cross-sectional view cut along line A-A′ of FIG. 14 is substantially the same as that of FIG. 7. The method illustrated with reference to FIGS. 13 to 15 may be substantially the same as or similar to that illustrated with reference to FIGS. 4 to 10 except for an edge portion 163 of the gate structure 160. Thus, like reference numerals refer to like elements, and detailed explanations thereabout may be omitted herein.

First, processes substantially the same as or similar to those illustrated with reference to FIG. 4 may be performed. Thereafter, referring to FIGS. 13 and 5, a mask layer 150, a second gate electrode layer 140, a first gate electrode layer 130 and a gate insulation layer 120 may be patterned sequentially to form a gate structure 160.

According to the patterning process, a portion of the gate structure 160 on a middle portion of the active region 105 in the first direction may have a first width D1 in the second direction, and portions of the gate structure 160 arranged on both end portions of the active region 105 in the first direction may have a second width D2 in the second direction. The second width D2 may be smaller than the first width D1. That is, the gate structure 160 may be formed to include a central portion 161 having the first width D1 on the middle portion of the active region 105 in the first direction, and edge portions 163 having the second width D2 on the both end portions of the active region 105 in the first direction and being connected to the central portion 161. In example embodiments, the edge portions 163 of the gate structure 160 may be also formed on portions of the isolation layer pattern 110 adjacent to the both end portions of the active region 105 in the first direction, and thus the gate structure 160 may extend in the first direction.

Referring to FIGS. 14, 15 and 7, after a spacer 170 may be formed on a sidewall of the gate structure 160, impurity regions 180 may be formed at upper portions of the active region 105 adjacent to end portions of the gate structure 160 in the second direction. In example embodiments, the impurity regions 180 may be formed to extend in the first direction with a uniform width in the second direction in the active region 105. Thus, the impurity regions 180 may be formed adjacent to the central portion 161 of the gate structure 160 but not adjacent to the edge portions 163 of the gate structure 160.

The impurity regions 180 may be formed by performing an ion implantation process using an ion implantation mask (not shown) having openings (not shown), which may extend in the first direction adjacent to the end portions of the gate structure 160 in the second direction. In example embodiments, each impurity region 180 may be formed to include first and second impurity regions 181 and 183, and thus the impurity regions 180 and the gate structure 160 may form a high voltage transistor.

Alternatively, as shown in FIG. 15, a mask 185 having a width substantially equal to or greater than the first width D1 of the gate structure 160 in the second direction and covering the edge portions 163 of the gate structure 160 and portions of the active region 105 adjacent thereto may be used as an ion implantation mask to perform an ion implantation process for forming the impurity regions 180. In this case, the impurity regions 180 may be formed not to include the second impurity region 183 but include the first impurity region 181 only, so that the impurity regions 180 and the gate structure 160 may form a low voltage transistor.

Thereafter, processes substantially the same as or similar to those illustrated with reference to FIGS. 10 and 1 to 3 may be performed. Accordingly, an insulating interlayer 190 and a contact plug 210 may be formed.

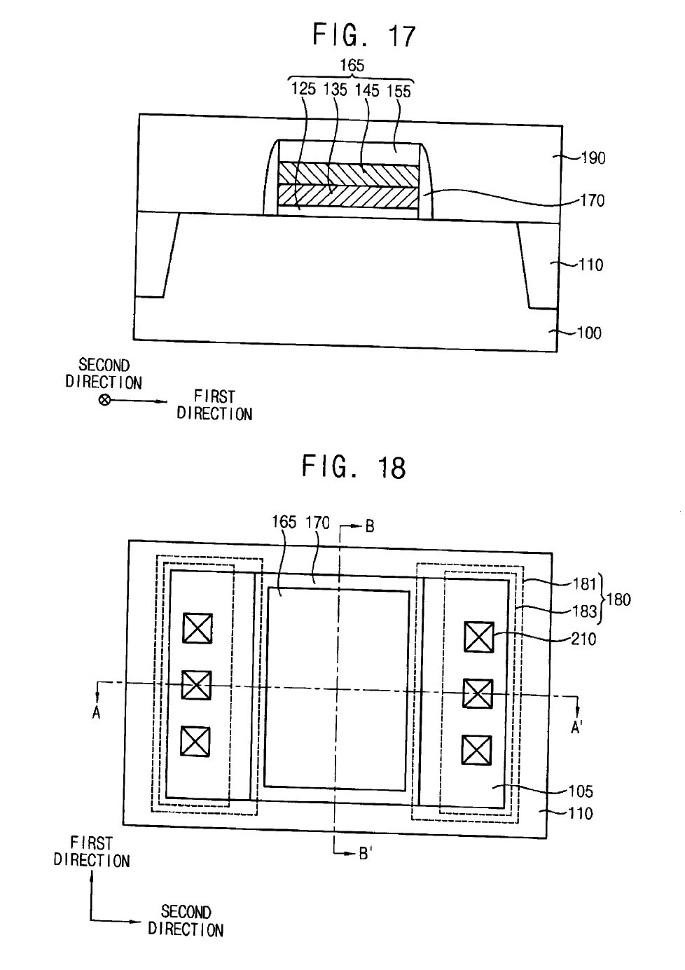

FIGS. 16 and 18 are plan views illustrating a transistor in accordance with still other example embodiments, and FIGS. 17 and 19 are cross-sectional views illustrating the transistor. Particularly, FIG. 17 is a cross-sectional view cut along line B-B′ of FIG. 16, and FIG. 19 is a cross-sectional view cut along line B-B′ of FIG. 18. The line B-B′ extends in a first direction. Each Cross-sectional view cut along line A-A′ of FIGS. 16 and 18 may be substantially the same as that of FIG. 2. The transistor of FIGS. 16 to 19 may be substantially the same as or similar to that illustrated with reference to FIGS. 1 to 3 except for a gate structure 165. Thus, like reference numerals refer to like elements, and detailed explanations thereabout may be omitted herein.

Referring to FIGS. 16 to 19 and 2, the transistor may include a substrate 100, a gate structure 161 and impurity regions 180.

The substrate 100 may be divided into an active region 105 and a field region by an isolation layer pattern 110 formed on the substrate 100.

The gate structure 165 may be formed on the active region 105 to have a smaller width than that of the active region 105 in the first direction, and thus the gate structure 165 may not be formed on end portions of the active region 105 in the first direction. In example embodiments, as shown in FIG. 16, the gate structure 165 may be formed on a middle portion of the active region 105 but may not be formed on end portions of the active region and portions of the isolation layer pattern 110 adjacent thereto in the first direction. The gate structure 165 may be also formed to have a smaller width than that of the active region 105 in the second direction.

The gate structure 165 may include a gate insulation layer pattern 125, a first gate electrode 135, a second gate electrode 145 and a mask 155 sequentially stacked on the substrate 100. In some embodiments, the gate structure 165 may not include the second gate electrode 145 but include the first gate electrode 135 only.

A sidewall of the gate structure 165 may be substantially surrounded by a spacer 170. The gate structure 165 may be formed only on the middle portion of the active region, and thus the spacer 170 may be formed only on the middle portion of the active region 105 but need not be formed on the field region as shown in FIG. 16.

Alternatively, as shown in FIG. 18, the spacer 170 may be formed on both end portions of the active region 105 in the first direction. In some embodiments, the spacer 170 may also be formed on portions of the isolation layer patter 110 adjacent thereto.

Impurity regions 180 may be formed at upper portions of the active region 105 adjacent to end portions of the gate structure 165 in the second direction. In example embodiments, the impurity regions 180 may extend in the first direction with a substantially uniform width in the second direction in the active region 105.

In example embodiments, the impurity regions 180 may include first and second impurity regions 181 and 183, so that the impurity regions 180 and the gate structure 165 may form a high voltage transistor. Alternatively, in example embodiments, the impurity regions 180 may not include the second impurity region 183 but include the first impurity region 181 only. In this case, the impurity regions 180 and the gate structure 165 may form a low voltage transistor. The impurity regions 180 may serve as source and drain regions of the transistors.

The impurity regions 180, the gate structure 165 and the spacer 170 may be covered by an insulating interlayer 190 on the substrate 100. A contact plug 210 may be formed through the insulating interlayer 190 to contact a top surface of each impurity region 180.

As illustrated above, the transistor may include the gate structure 165 only on the middle portion of the active region 105. Thus, the transistor may be not formed at an interface between the field region and the active region 105 in the first direction. As a result, a threshold voltage variation may be reduced, and a hump phenomenon and/or HEIP may not be generated in the transistor.

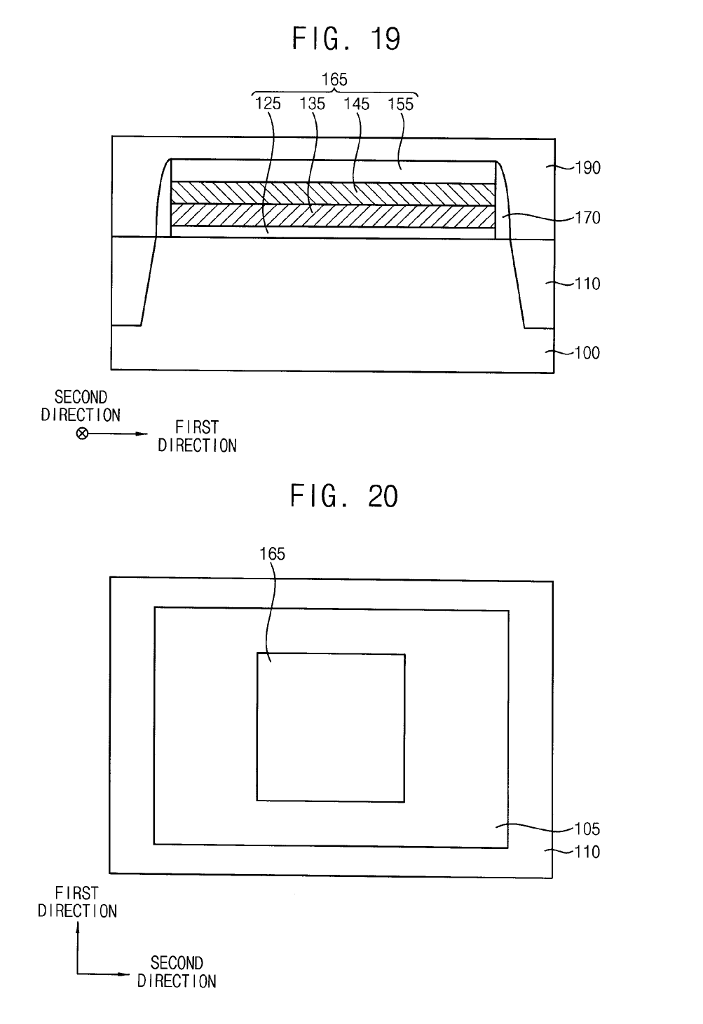

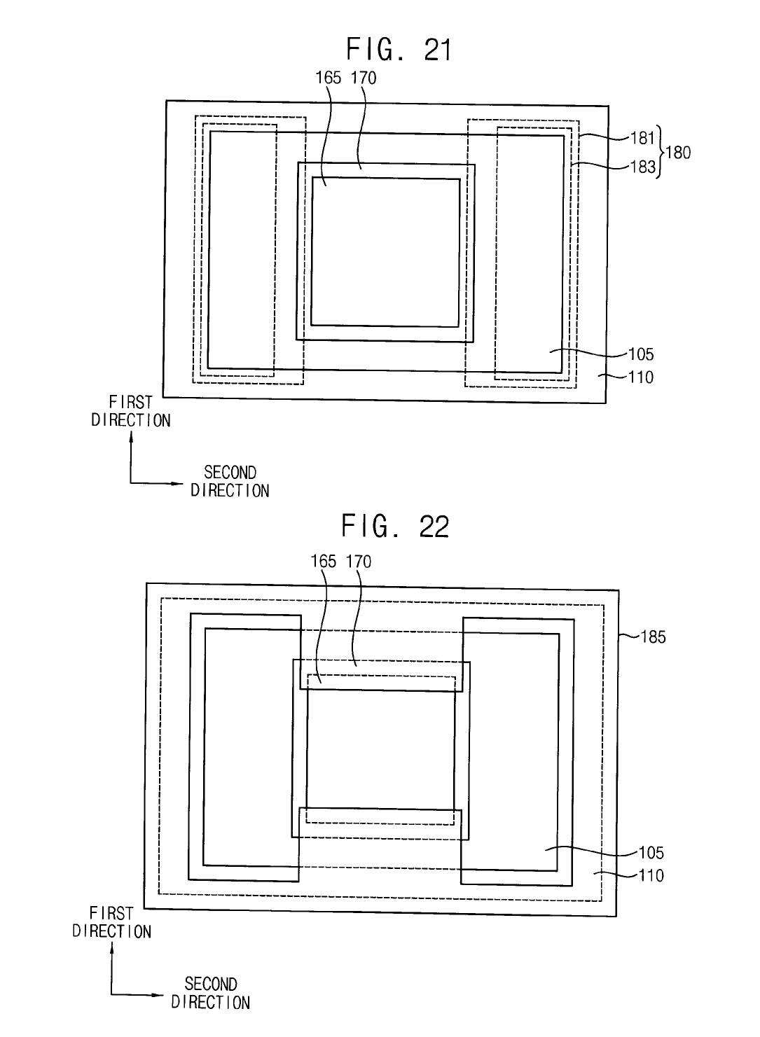

FIGS. 20 to 22 are plan views illustrating stages of a method of manufacturing a transistor in accordance with still other example embodiments. A cross-sectional view cut along line A-A′ of FIG. 20 is substantially the same as that of FIG. 5, and a cross-sectional view cut along line A-A′ of FIG. 21 is substantially the same as that of FIG. 7. The method illustrated with reference to FIGS. 20 to 22 may be substantially the same as or similar to that illustrated with reference to FIGS. 4 to 10 and/or that illustrated with reference to FIGS. 13 to 15 except for a gate structure 165. Thus, like reference numerals refer to like elements, and detailed explanations thereabout may be omitted herein.

First, processes substantially the same as or similar to those illustrated with reference to FIG. 4 may be performed. Thereafter, referring to FIGS. 20 and 5, a mask layer 150, a second gate electrode layer 140, a first gate electrode layer 130 and a gate insulation layer 120 may be patterned sequentially to form a gate structure 165.

According to the patterning process, the gate structure 165 may be formed on the active region 105 to have a smaller width than that of the active region 105 in the first direction, and thus the gate structure 165 may not be formed at an interface between the active region 105 and the field region or portions of the isolation layer pattern 110 adjacent thereto in the first direction. The gate structure 165 may be also formed to have a smaller width than that of the active region 105 in the second direction.

Referring to FIGS. 21 and 7, after a spacer 170 may be formed on a sidewall of the gate structure 165, impurity regions 180 may be formed at upper portions of the active region 105 adjacent to end portions of the gate structure 165 in the second direction. In example embodiments, the impurity active regions 180 may be formed to extend in the first direction with a substantially uniform width in the second direction in the active region 105.

The spacer 170 may substantially surround the sidewall of the gate structure 165. The gate structure 165 may be formed only on a substantially middle portion of the active region 105, and thus the spacer 170 may not be formed on the field region. Alternatively, the spacer 170 may be formed on both end portions of the active region 105 along first direction. In some embodiments, the spacer 170 may be also formed on portions of the isolation layer patter 110 adjacent thereto.

The impurity regions 180 may be formed by performing an ion implantation process using an ion implantation mask (not shown) having openings (not shown), which may extend in the first direction adjacent to the end portions of the gate structure 165 in the second direction. Alternatively, as shown in FIG. 22, a mask 185 having a width substantially equal to or greater than the width of the gate structure 165 in the second direction and covering exposed portions of the active region 105 by the gate structure 165 in the first direction may be used as the mask to perform an ion implantation process for forming the impurity regions 180.

In example embodiments, an ion implantation mask may not be used for formation of the impurity regions 180. That is, when the gate structure 165 is formed on the active region 105 and the spacer 170 is formed on the end portions of the active region 105 and/or the portions of the isolation layer patter 110 adjacent thereto in the first direction as shown in FIG. 18, a middle portion of the active region 105 in the second direction may be covered by the gate structure 165 and the spacer 170. Thus, the gate structure 165 and the spacer 170 may serve as an ion implantation mask. As a result, even though an ion implantation mask may not be formed, the impurity regions 180 may be formed at the exposed upper portions of active region 105 adjacent to the end portions of the gate structure 165 in the second direction. In this case, the impurity regions 180 may include only a first impurity region 181, but need not include a second impurity region 183, so that the impurity regions 180 and the gate structure 165 may form a low voltage transistor.

Thereafter, processes substantially the same as or similar to those illustrated with reference to FIGS. 10 and 1 to 3 may be performed. Accordingly, an insulating interlayer 190 and a contact plug 210 may be formed.

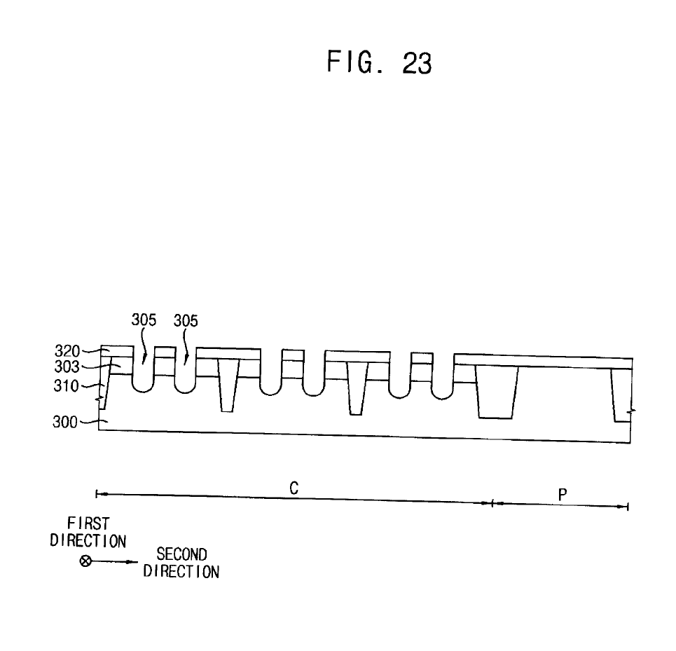

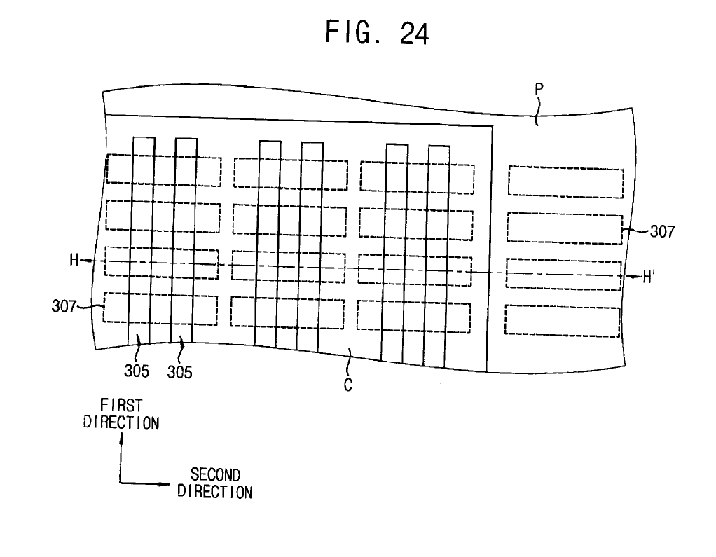

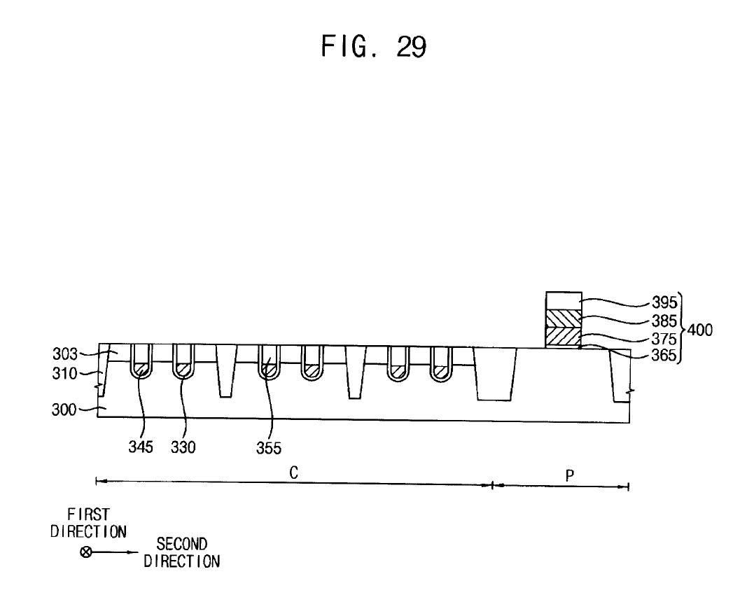

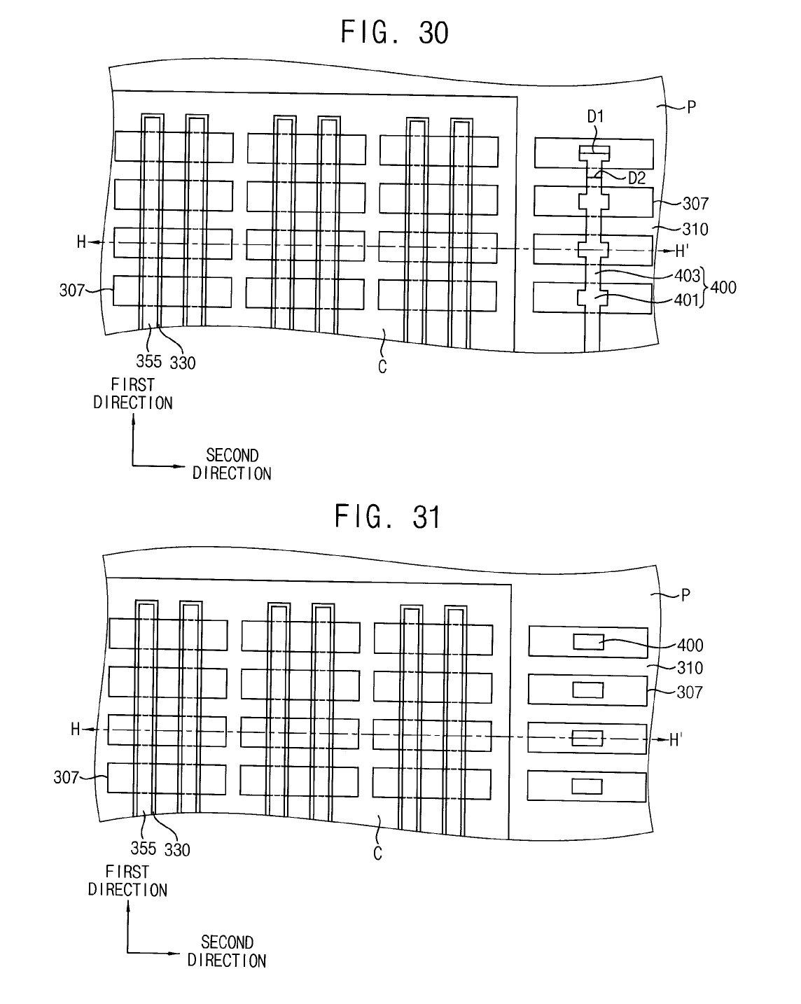

FIGS. 23, 25 to 29, 32, and 36 to 56 are cross-sectional views illustrating stages of a method of manufacturing a semiconductor device in accordance with example embodiments, and FIGS. 24, 30, 31 and 33 to 35 are plan views illustrating stages of a method of manufacturing the transistor. Particularly, FIG. 23 is a cross-section view cut along line H-H′ of FIG. 24, FIG. 29 is a cross-section view cut along line H-H′ of FIGS. 30 and 31, and FIG. 32 is a cross-section view cut along line H-H′ of FIGS. 33 to 35. A cell region C and a peripheral region P of a substrate are shown in the cross-sectional views and the plan views.

Referring to FIGS. 23 and 24, impurities may be implanted into an upper portion of a substrate 300 in the cell region C to form a first impurity region 303, and an isolation layer pattern 310 may be formed on the substrate 300 to divide the substrate 300 into an active region 307 and a field region. Thereafter, a first mask 320 may be formed on the substrate 300, and some upper portions of the substrate 300 may be removed in the cell region C using the first mask as an etching mask to form a second trench 305.

The substrate 300 may be a silicon substrate, a germanium substrate, a silicon-germanium substrate, a silicon-on-insulator (SOI) substrate, a germanium-on-insulator (GOI) substrate, etc.

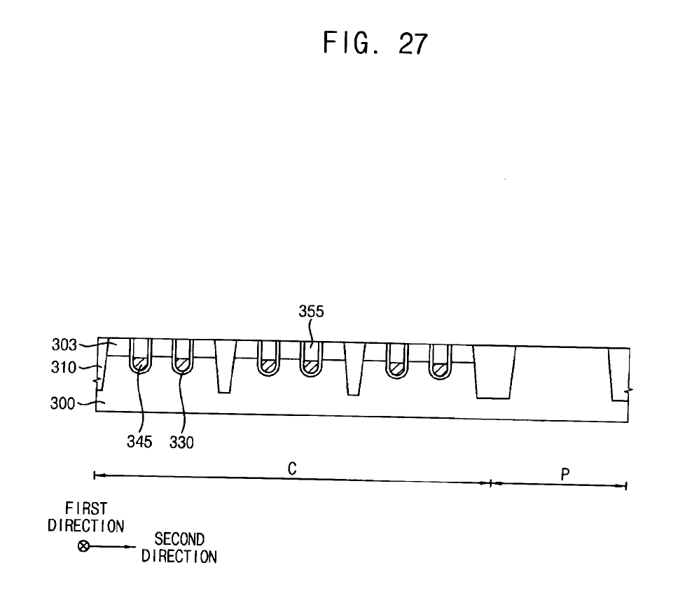

The first impurity region 303 may be formed by performing an ion implantation process on the substrate 300, and may include, e.g., n-type impurities such as phosphorus, arsenic, etc., or p-type impurities such as boron, gallium, etc. The first impurity region 303 and a first gate structure to be formed later (See FIG. 27) collectively form a first transistor, with the first impurity region 303 serving as source and drain regions of the first transistor.

The isolation layer pattern 310 may be formed by forming a first trench (not shown) at the upper portion of the substrate 300, forming an isolation layer on the substrate 300 to sufficiently fill the first trench, and planarizing an upper portion of the isolation layer until a top surface of the substrate 300 may be exposed. The isolation layer may be formed to include an oxide, for example, silicon oxide.

In some embodiments, the first impurity region 303 can be formed after the isolation layer pattern 310 is formed.

The second trench 305 may extend in the first direction, and a plurality of second trenches 305 may be formed in the second direction. In example embodiments, two second trenches 305 may be formed within each active region 307 divided by the isolation layer pattern 110.

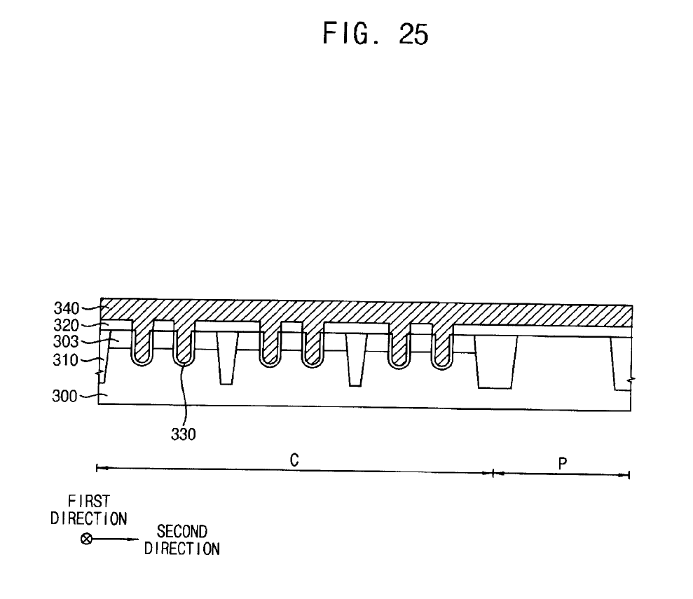

Referring to FIG. 25, a first gate insulation layer 330 may be formed on an inner wall of the second trench 305, and a first gate electrode layer 340 may be formed on the first gate insulation layer 330 and the first mask 320 to sufficiently fill the second trench 305.

In example embodiments, the first gate insulation layer 330 may be formed by performing a thermal oxidation process or a chemical vapor deposition (CVD) process on an upper portion of the substrate 300 exposed through the second trench 305. The first gate insulation layer 330 may include an oxide, for example, silicon oxide.

The first gate electrode layer 340 may be formed to include a metal such as tungsten (W), titanium (Ti), tantalum (Ta), etc., a metal nitride and/or a metal silicide.

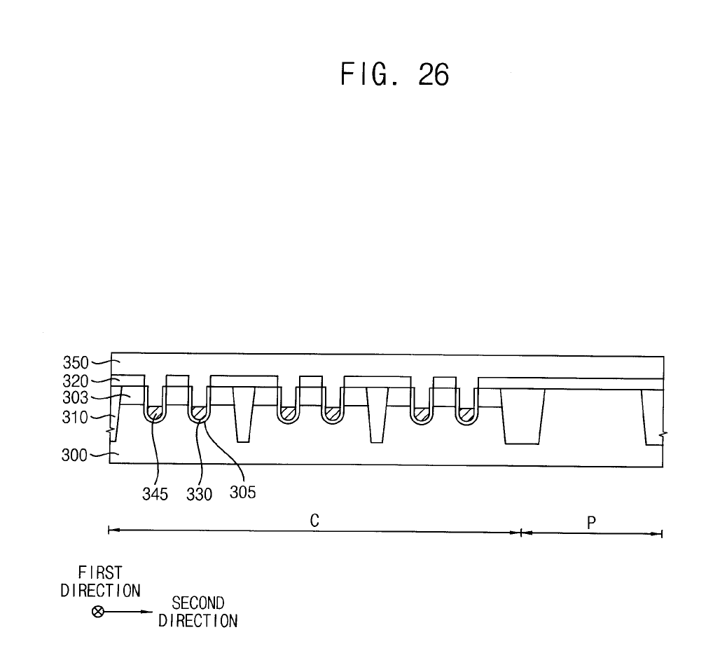

Referring to FIG. 26, an upper portion of the first gate electrode layer 340 may be removed to form a first gate electrode 345 partially filling the second trench 305, and a first capping layer 350 may be formed on the first gate electrode 345, the first gate insulation layer 330 and the first mask 320 to fill a remaining portion of the second trench 305.

In example embodiments, the first gate electrode layer 340 may be removed by a chemical mechanical polishing (CPM) process and/or an etch back process. Accordingly, the first gate electrode 345 may be formed in a lower portion of the second trench 305, extending in the first direction, and a plurality of first electrodes 345 may be formed in the second direction. When the first gate electrode 345 is formed, a portion of the first gate insulation layer 330 may be removed. In this case, the first gate insulation layer 330 may be formed on an inner wall of the lower portion of the second trench 305.

The first capping layer 350 may include a nitride, for example, silicon nitride.

Referring to FIG. 27, an upper portion of the first capping layer 350 and the first mask 320 may be removed by, e.g., a CMP process until the top surface of the substrate 300 may be exposed. Accordingly, a first capping layer pattern 355 may fill an upper portion of the second trench 305. The first capping layer pattern 355 may extend in the first direction, and a plurality of first capping layer patterns 355 may be formed in the second direction.

The first gate insulation layer 330, the first gate electrode 345 and the first capping layer pattern 355 may form a first gate structure mentioned above. That is, the first gate structure may be a buried gate structure filling the second trench 305. The first gate structure may be formed in the cell region C of the substrate 300, extending in the first direction, and a plurality of first gate structures may be formed in the second direction.

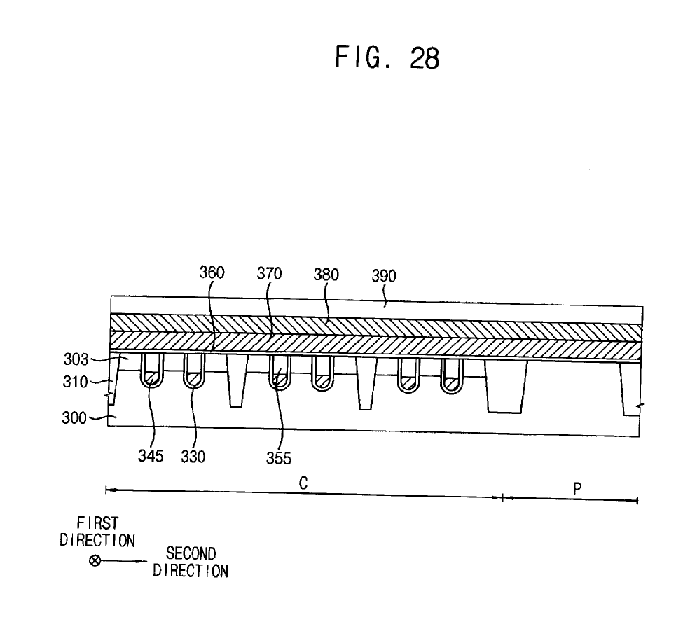

Referring to FIG. 28, a second gate insulation layer 360, a second gate electrode layer 370, a third gate electrode layer 380 and a second mask layer 390 may be formed on the substrate 300 both in the cell region C and the peripheral region P.

The second gate insulation layer 360 may include an oxide, for example, silicon oxide. The second and third gate electrode layers 370 and 380 may include a conductive material, e.g., a metal such as tungsten (W), etc., and/or polysilicon doped with impurities. The second mask layer 390 may include a nitride, for example, silicon nitride.

Referring to FIGS. 29 to 30, the second gate insulation layer 360, the second gate electrode layer 370, the third gate electrode layer 380 and the second mask layer 390 may be patterned to form a second gate structure 400 including a second gate insulation layer pattern 365, a second gate electrode 375, a third gate electrode 385 and a second mask 395 sequentially stacked on the substrate 300 in the peripheral region P.

In some example embodiments, according to the patterning process, as shown in FIG. 30, the second gate structure 400 may have a portion, e.g., central portion, on a substantially middle portion of the active region 307 in the first direction in the peripheral region P, which may have a first width D1 in the second direction. The second gate structure 400 may also have another portion (e.g., an edge portion) arranged on at least one end portion of the active region 307 in the first direction in the peripheral region P, which may have a second width D2 in the second direction. The second width D2 may be smaller than the first width D1. That is, in some embodiments, the second gate structure 400 may include a central portion 401 having the first width D1 on the substantially middle portion of the active region 307 in the first direction, and an edge portion 403 having the second width D2 on at least one end portion of the active region 307 in the first direction and being connected to the central portion 401. In example embodiments, the edge portion 403 of the second gate structure 400 may also be formed on a portion of the isolation layer pattern 310 adjacent to the at least one end portion of the active region 307 in the first direction, so that the second gate structure 400 may extend in the first direction.

Alternatively, as shown in FIG. 31, the second gate structure 400 may be formed to have a smaller width than that of the active region 307 in the first direction, and thus the second gate structure 400 may not be formed at an interface between the active region 307 and the field region or a portion of the isolation layer pattern 310 adjacent thereto in the first direction. The second gate structure 400 may also be formed to have a smaller width than that of the active region 307 in the second direction.

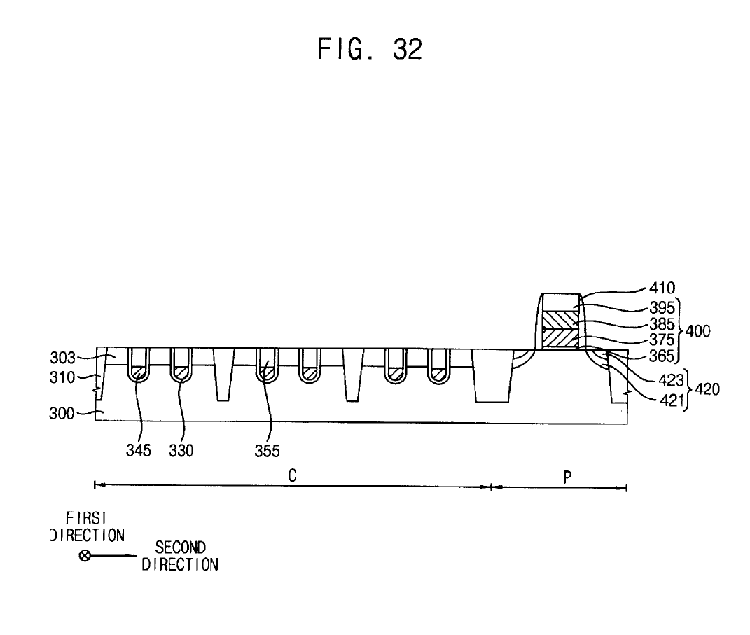

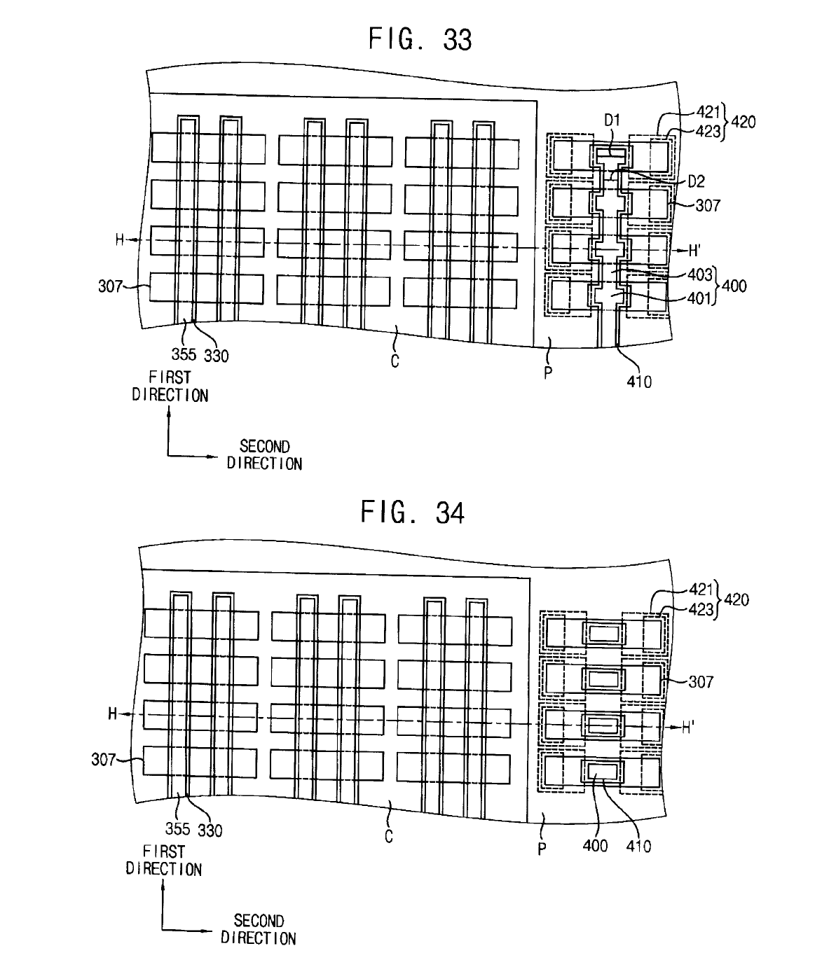

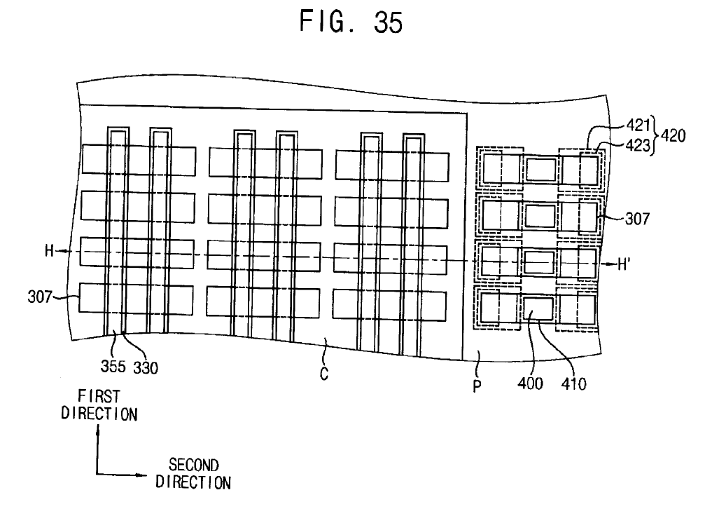

Referring to FIGS. 32 to 33, a first spacer 410 may be formed on a sidewall of the second gate structure 400, and impurity regions 420 may be formed at upper portions of the active region 307 adjacent to end portions of the second gate structure 400 in the second direction. In example embodiments, the impurity regions 420 may be formed in the active region 307. The impurity regions 420 may extend in the first direction with a substantially uniform width in the second direction. The impurity regions 420 and the second gate structure 400 may form a second transistor with the impurity regions 420 serving as source and drain regions of the second transistor.

The first spacer 410 may be formed by forming a first spacer layer on the substrate 300 and the second gate structure 400, and anisotropically etching the first spacer layer. Accordingly, the first spacer 410 may surround a sidewall of the second gate structure 400. The first spacer layer may include a nitride, for example, silicon nitride.

In example embodiments, when the second gate structure 400 extends in the first direction, the first spacer 410 may also extend in the first direction as shown in the FIG. 33.

Alternatively, as shown in FIG. 34, in some other embodiments, when the second gate structure 400 is formed only on the middle portion of the active region 307 in the first direction, the first spacer 410 may also be formed on the middle portion of the active region 307 in the first direction. Alternatively, the first spacer 410 may be formed on both end portions of the active region 307 and portions of the isolation layer pattern 310 adjacent thereto as shown in FIG. 35. Also see FIG. 18.

In example embodiments, the impurity regions 420 may be formed by performing an ion implantation process using an ion implantation mask (not shown) having openings (not shown), which may extend in the first direction adjacent to the end portions of the second gate structure 400 in the second direction. In this case, the impurity regions 420 may include a second impurity region 421 having a lower impurity concentration and a third impurity region 423 having a higher impurity concentration. Thus, the impurity regions 420 and the second gate structure 400 may form a high voltage transistor

Alternatively, in example embodiments, a mask (not shown) having a width equal to or greater than a width of the portion of the second gate structure 400 on a middle portion of the active region 307 in the second direction and covering the edge portions 403 of the second gate structure 400 and/or exposed portions of the active region 307 by the second gate structure 400 in the first direction may be used as an ion implantation mask to perform an ion implantation process for forming the impurity regions 420. In this case, the impurity regions 420 may not include the third impurity region 423 but include the second impurity region 421 only. Thus, the impurity regions 420 and the second gate structure 400 may form a low voltage transistor.

Alternatively, in example embodiments, an ion implantation mask may not be used for formation of the impurity regions 420. That is, when the second gate structure 400 is formed on the active region 307 and the first spacer 410 is formed on the end portions of the active region 307 and/or the portions of the isolation layer pattern 310 adjacent thereto in the first direction as shown in FIG. 35, a middle portion of the active region 307 in the second direction may be covered by the second gate structure 400 and the first spacer 410. Thus, the second gate structure 400 and the first spacer 410 may serve as an ion implantation mask. As a result, even when an ion implantation mask is not be used, the impurity regions 420 may be formed at the exposed upper portions of active region 307 adjacent to the end portions of the second gate structure 400 in the second direction. In this case, impurity regions 420 may include only a second impurity region 421, but need not include a third impurity region 423, so that the impurity regions 420 and the second gate structure 400 may form a low voltage transistor.

In some embodiments, after impurity regions 420 may be formed, the second gate structure 400 may be formed.

As described above, the second transistor including the second gate structure 400 and the impurity regions 420 may be formed only at the middle portion of the active region 307 in the first direction in the peripheral region P. Thus, a threshold voltage variation may be reduced, and a hump phenomenon and/or HEIP may not be generated in the transistor.

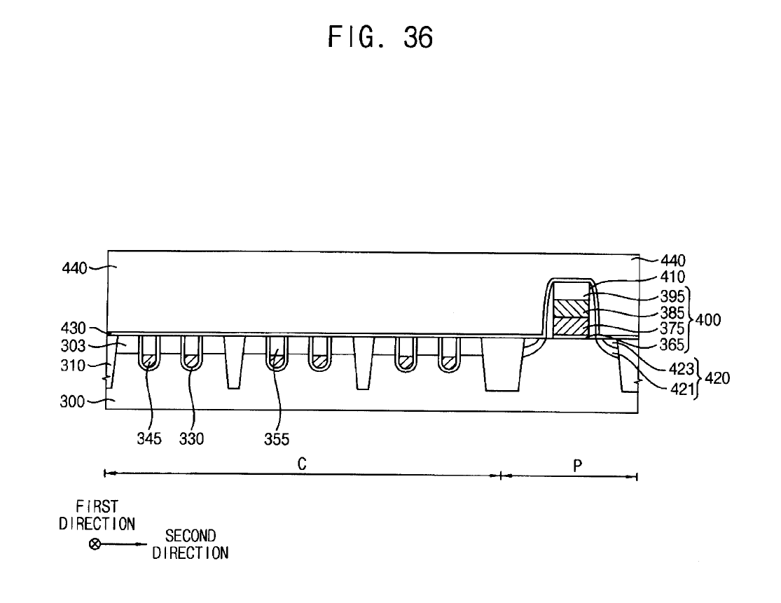

Referring to FIG. 36, an etch stop layer 430 may be formed on the substrate 300, the isolation layer pattern 310, the first impurity region 303 and the first gate structure in the cell region C, and on the second gate structure 400, the first spacer 410 and the impurity regions 420 in the peripheral region P. A first insulating interlayer 440 covering the second gate structure 400 may be formed on the etch stop layer 430 both in the cell region C and the peripheral region P.

The etch stop layer 430 may include a nitride, for example, silicon nitride. Accordingly, the etch stop layer 430 may include a material substantially the same as that of the second mask 395 of the second gate structure 400, thereby to be merged thereto.

The first insulating interlayer 440 may include an oxide, for example, boro phospho silicate glass (BPSG), undoped silicate glass (USG) and spin on glass (SOG) and so on. A portion of the first insulating interlayer 440 in the cell region C may be removed in subsequent processes, and thus may serve as a sacrificial layer.

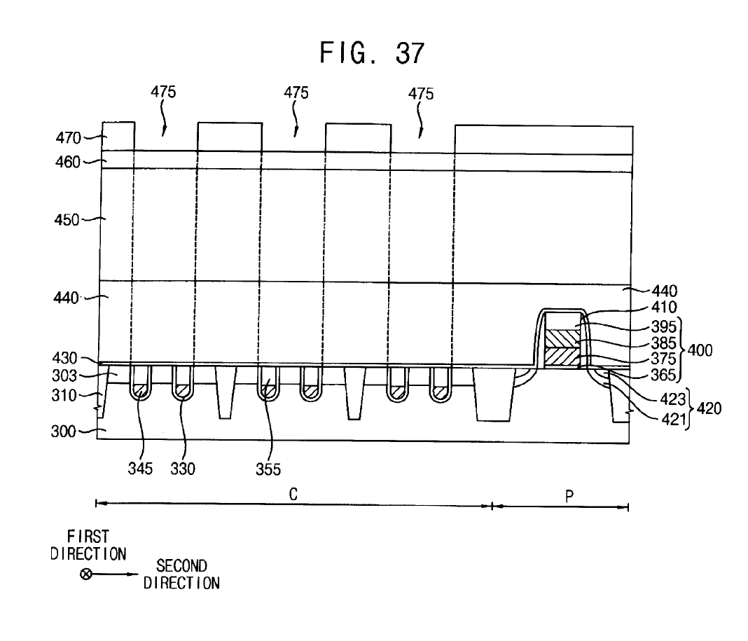

Referring to FIG. 37, a silicon-on-hardmask (SOH) layer 450, a silicon oxynitride layer 460 and a first photoresist pattern 470 may be sequentially formed on the first insulating interlayer 440 both in the cell region C and the peripheral region P.

The first photoresist pattern 470 may include first openings 475 exposing portions of a top surface of the silicon oxynitride layer 460 in the cell region C. Each first opening 475 may extend in the first direction, and a plurality of first openings 475 may be formed in the second direction. In example embodiments, each first opening 475 may overlap two of the first gate structures adjacent to each other in each active region 307 and a portion of the substrate 300 therebetween.

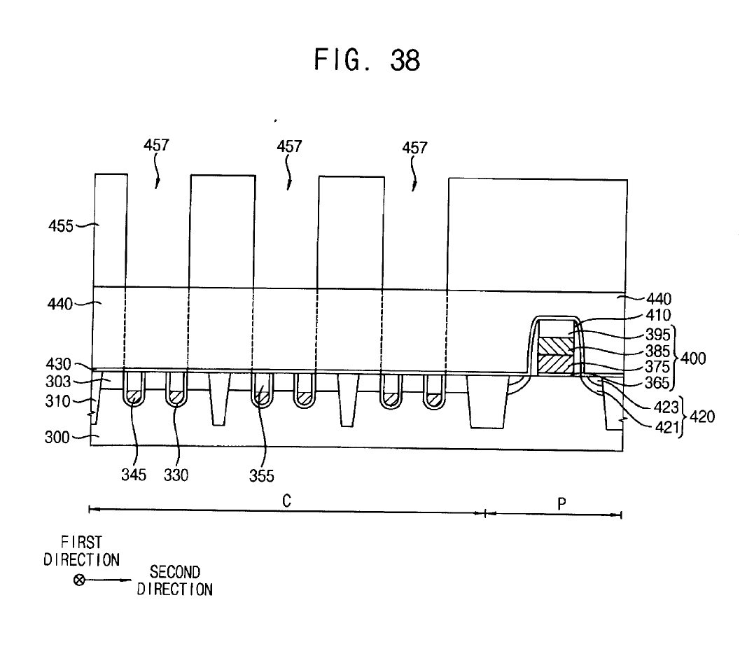

Referring to FIG. 38, the silicon oxynitride layer 460 and the SOH layer 450 may be sequentially etched using the first photoresist pattern 470 (FIG. 37) as an etching mask. Accordingly, a SOH layer pattern 455 may be formed to include second openings 457 exposing portions of a top surface of the first insulating interlayer 440 in the cell region C.

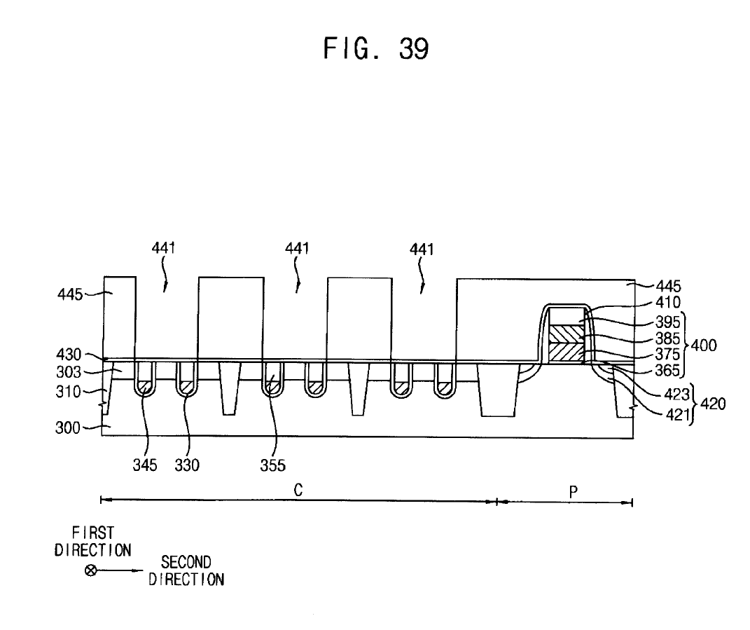

Referring to FIG. 39, the first insulating interlayer 440 may be etched using the SOH layer pattern 455 as an etching mask. Accordingly, the exposed portions of the first insulating interlayer 440 may be removed in the cell region C, so that a first insulating interlayer pattern 445 having third openings 441 may be formed, and portions of a top surface of the etch stop layer 430 may be exposed in the cell region C.

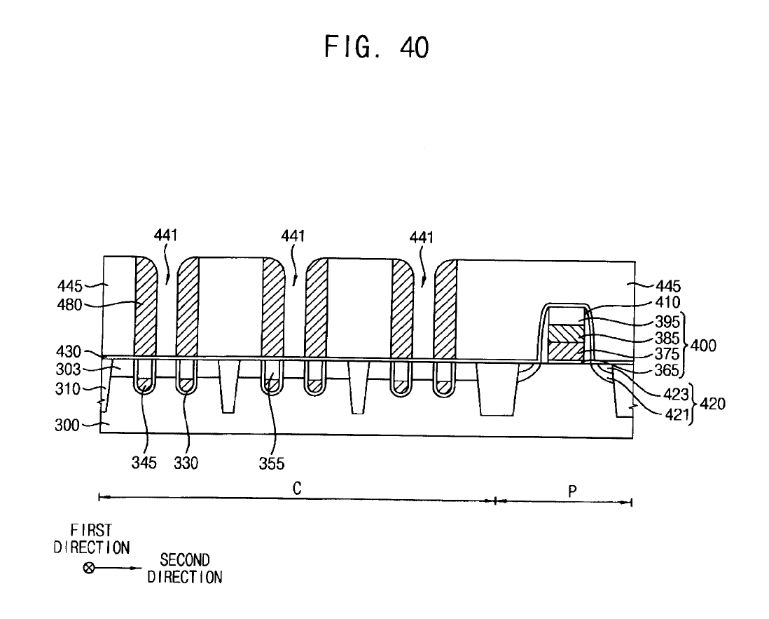

Referring to FIG. 40, a second spacer 480 may be formed on a sidewall of each third opening 441.

The second spacer 480 may be formed by forming a second spacer layer on the sidewalls of the third openings 441, the exposed portions of the etch stop layer 430 and the first insulating interlayer pattern 445, and anisotropically etching the second spacer layer. Accordingly, two second spacers 480 may be formed on each active region 307 in the cell region C, and each second spacer 480 may be formed to overlap the first gate structure. Each third opening 441 may extend in the first direction, and a plurality of third openings 441 may be arranged in the second direction. Thus, each second spacer 480 may extend in the first direction, and a plurality of second spacers 480 may be arranged in the second direction. The second spacer layer may be formed to include a nitride, for example, silicon nitride.

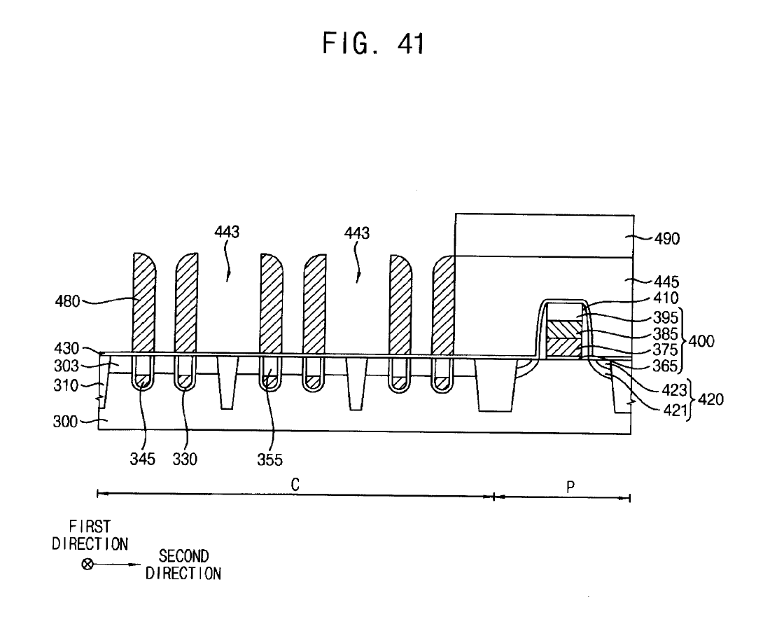

Referring to FIG. 41, a third mask 490 may be formed on a portion of the first insulating interlayer pattern 445, and exposed portions of the first insulating interlayer pattern 445 not covered by the third mask 490 may be removed to form fourth openings 443 exposing portions of a top surface of the etch stop layer 430.

In example embodiments, the third mask 490 may cover substantially the entire portion of the first insulating interlayer pattern 445 in the peripheral region P and a portion of the first insulating interlayer pattern 445 in the cell region C adjacent thereto. Thus, a portion of the first insulating interlayer pattern 445 in a central portion of the cell region C may be exposed.

The exposed portions of the first insulating interlayer pattern 445 may be removed by, for example, a wet etching process. The second spacers 480 may remain on the substrate 300 in the cell region C, and may be spaced apart from each other in the second direction.

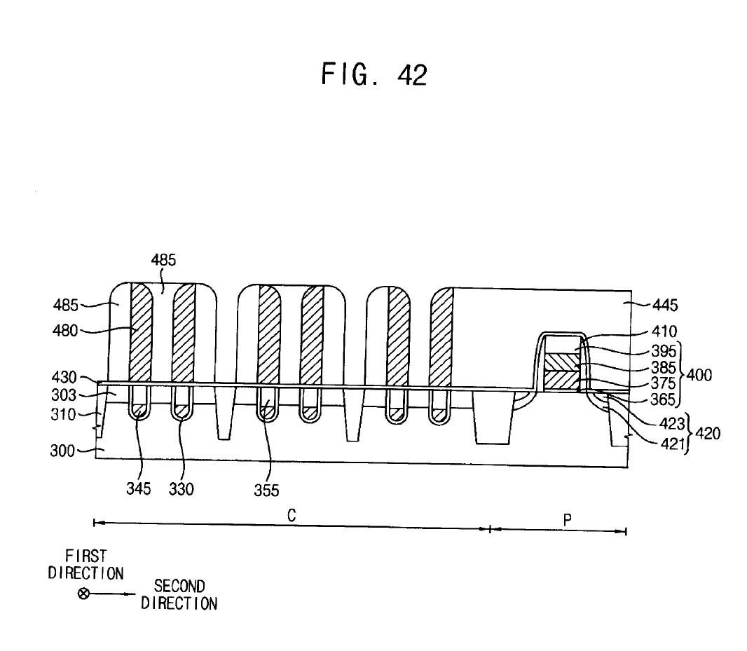

Referring to FIG. 42, after the third mask 490 is removed, third spacers 485 contacting the second spacers 480 may be formed on the substrate 300.

In example embodiments, the third spacers 485 may be formed by forming a third spacer layer on the etch stop layer 430 and the first insulating interlayer pattern 445 to cover the second spacers 480, and anisotropically etching the third spacer layer. The third spacer layer may include an oxide, for example, silicon oxide, and thus a portion of the third spacer layer contacting the first insulating interlayer pattern 445 may be merged thereto.

In example embodiments, the third spacers 485 may sufficiently fill spaces between two of the second spacers 480 which are spaced apart from each other in the second direction on each active region 307, and may partially fill spaces between two of the second spacers 480 adjacent to each other which define the fourth opening 443. That is, portions of the exposed top surface of the etch stop layer 430 by the fourth openings 443 may not be completely covered by the thirds spacers 385.

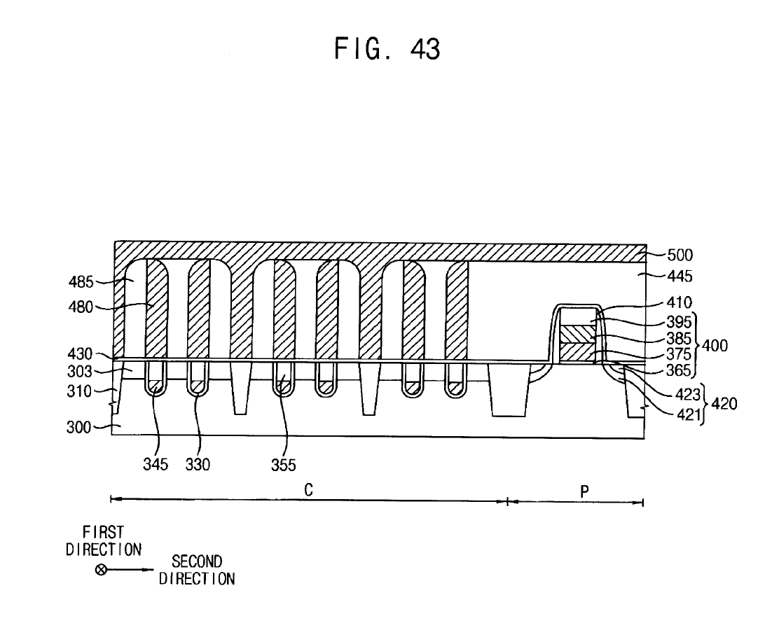

Referring to FIG. 43, a filling layer 500 may be formed on the etch stop layer 430, the second spacers 480, the third spacers 485 and the first insulating interlayer pattern 445 to fill remaining portions of the fourth openings 443.

In example embodiments, the filling layer 500 may be formed to include a material substantially the same as that of the second spacers 480, i.e., a nitride such as silicon nitride.

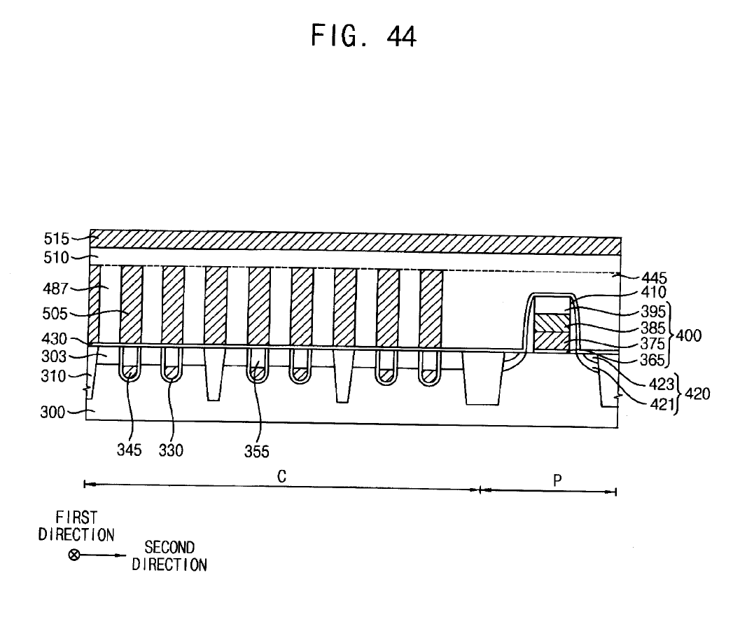

Referring to FIG. 44, an upper portion of the filling layer 500, upper portions of the second spacers 480, upper portions of the third spacers 485 and an upper portion of the first insulating interlayer pattern 445 may be planarized to form first and second patterns 505 and 487 in the cell region C. Second and third capping layers 510 and 515 may be formed sequentially in the cell region C and the peripheral region P.

In example embodiments, the planarizing process may be performed by a CMP process and/or an etch back process.

According to the planarization process, the second spacers 480 and the filling layer 500 may become the first patterns 505, and the third spacers 485 may become the second patterns 487. Thus, each of the first and second patterns 505 and 487 may extend in the first direction, and the first and second patterns 505 and 487 may be alternately and repeatedly formed in the second direction. The first and second patterns 505 and 487 may contact each other. In example embodiments, at least some of the first patterns 505 may overlap the first gate structure, and the others of the first patterns 505 may overlap the isolation layer pattern 310. In example embodiments, the second patterns 487 may overlap the first impurity region 303 adjacent to the first gate structure.

The second capping layer 510 may be formed to include an oxide, e.g., silicon oxide. The second capping layer 510 may cover top surfaces of the first and second patterns 505 and 487 and a top surface of the first insulating interlayer pattern 445, and may be combined with the second patterns 487 and the first insulating interlayer pattern 445. The third capping layer 515 may be formed to include a nitride, e.g., silicon nitride.

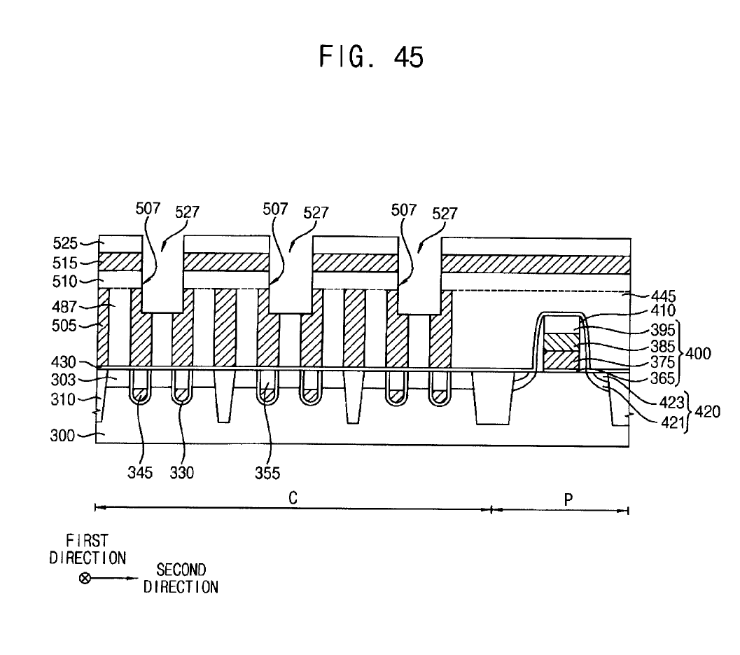

Referring to FIG. 45, after a second photoresist pattern 525 is formed on the third capping layer 515, the second and third capping layers 510 and 515 and upper portions of the first and second patterns 505 and 487 may be etched using the second photoresist pattern 525 as an etching mask to form recesses 507.

In example embodiments, the second photoresist pattern 525 may include fifth openings 527. Each fifth opening 527 may extend in the first direction, and a plurality of fifth openings 527 may be formed in the second direction. Each fifth opening 527 may overlap the second pattern 487 on a portion of the substrate 300 between the first gate structures adjacent to each other in each active region 307 and a portion of the first patterns 505 adjacent to the second pattern 487. Thus, the second patterns 487 on the substrate 300 between the first gate structures adjacent to each other in each active region 307 may be exposed by the recesses 507.

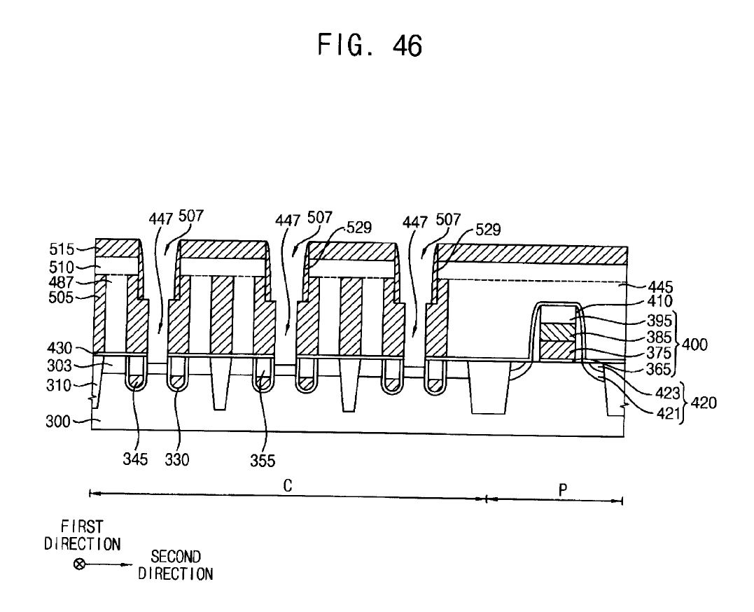

Referring to FIG. 46, the second photoresist pattern 525 may be removed, and an etch stop layer pattern 529 may be formed on sidewalls of the second and third capping layers 510 and 515 and upper sidewalls of the first patterns 505 exposed by each recess 507.

The etch stop layer pattern 529 may be formed by forming an etch stop layer on inner walls of the recesses 507 and the third capping layer 515, and etching the etch stop layer anisotropically. Thus, the etch stop layer pattern 529 may cover at least sidewalls of the second capping layer 510.

The etch stop layer pattern 529 may be formed to include a material substantially the same as that of the first patterns 505 and/or the third capping layer 515, i.e., a nitride such as silicon nitride. Thus, the etch stop layer pattern 529 may be merged thereto, and may have a high etching selectivity with respect to the second patterns 487 and/or the second capping layer 510. Accordingly, the second capping layer 510 may be prevented from being etched by the etch stop layer pattern 529 when a wet etching process for the second patterns 487 is subsequently performed.

The second patterns 487 exposed by the recesses 507 may be removed, and portions of the etch stop layer 430 thereunder may be removed to form sixth openings 447 exposing upper portions of the substrate 300 in the cell region C and being in fluid communication with the recesses 507, respectively. In example embodiments, the exposed second patterns 487 may be removed by, for example, a wet etching process, and the portions of the etch stop layer 430 thereunder may be removed by, for example, a dry etching process.

Each sixth opening 447 may be formed in the cell region C to extend in the first direction. The sixth opening 447 and the recess 507 in fluid communication therewith may be referred to simply as a seventh opening for the convenience of explanation.

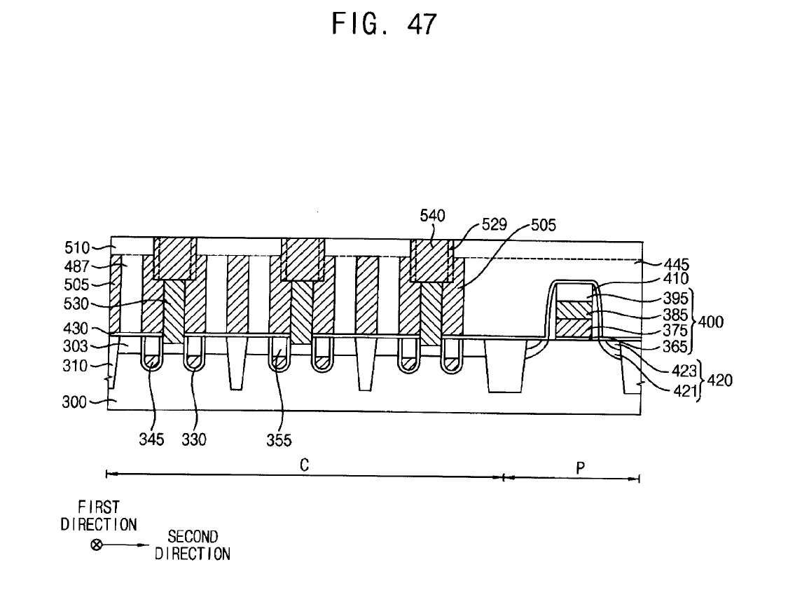

Referring to FIG. 47, a source line 530 may be formed to fill each sixth opening 447, and a fourth capping layer pattern 540 may be formed on the source line 530 to fill the each recess 507.

The source line 530 may be formed by forming a first conductive layer on the exposed upper portions of the substrate 300 in the cell region C to fill the sixth openings 447 and the recesses 507, and removing an upper portion of the first conductive layer. In some embodiments, portions of the first conductive layer in the recesses 507 may be removed. Accordingly, each source line 530 may extend in the first direction, and a plurality of source lines 530 may be formed in the second direction to fill lower portions of the each seventh opening. The first conductive layer may be formed to include a metal, e.g., tungsten (W), titanium (Ti), tantalum (Ta), etc., and a metal nitride, e.g., tungsten nitride, titanium nitride, tantalum nitride, etc.

The fourth capping layer pattern 540 may be formed by forming a fourth capping layer on the source lines 530, the etch stop layer patterns 529 and the third capping layer 515 in the cell region C to fill the recesses 507, and planarizing an upper portion of the fourth capping layer and the third capping layer 515 until a top surface of the second capping layer 510 may be exposed. Thus, the third capping layer 515 may be removed, and the fourth capping layer pattern 540 may fill the upper portions of the seventh openings. The fourth capping layer may be formed to include a nitride, for example, silicon nitride, and thus the fourth capping layer pattern 540 may be merged to the first patterns 505 and/or the etch stop layer patterns 529.

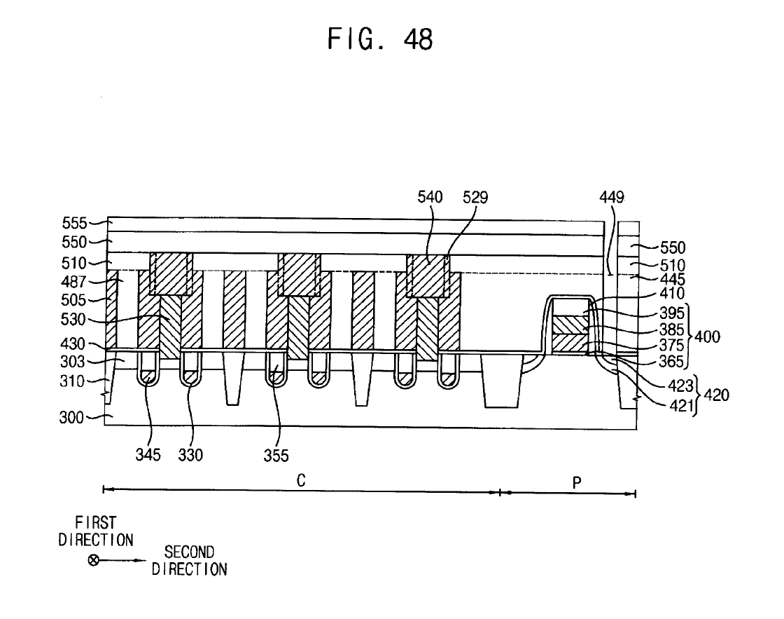

Thereafter, a fourth mask 550 (FIG. 48) exposing portions of the cell region C may be formed, and the second capping layer 510 and the second patterns 487 may be etched using the fourth mask 550 as an etching mask. In some embodiments, the etching process may be performed by, e.g., a dry etching process. During the dry etching process, portions of the etch stop layer 430 and the substrate 300 under the second patterns 487 may be also removed to form eighth openings (not shown) exposing upper portions of the substrate 300 in the cell region C.

An insulating layer (not shown) may be formed on the substrate 300, the first patterns 505, the fourth capping layer patterns 540 and the fourth mask 550 to sufficiently fill the eighth openings, and an upper portion of the insulating layer may be planarized until an upper portion of the fourth mask 550 may be removed to form third patterns (not shown). The insulating layer may include a nitride, for example, silicon nitride, and thus the insulating layer may be merged to the first patterns 505, the fourth capping layer patterns 540, the etch stop layer patterns 529 and the second capping layer 510.

In example embodiments, each third pattern may be formed in the cell region C to extend in the second direction, and a plurality of third patterns may be formed in the first direction.

Referring to FIG. 48, a fifth mask 555 exposing a portion of the peripheral region P may be formed. The fourth mask 550, the first insulating interlayer pattern 445 and the etch stop layer 430 may be etched using the fifth mask 555 as an etching mask to form a first contact hole 449. The first contact hole 449 may be formed to expose a portion of a top surface of the impurity regions 420 in the peripheral region P. The etching process may be formed by, e.g., a dry etching process.

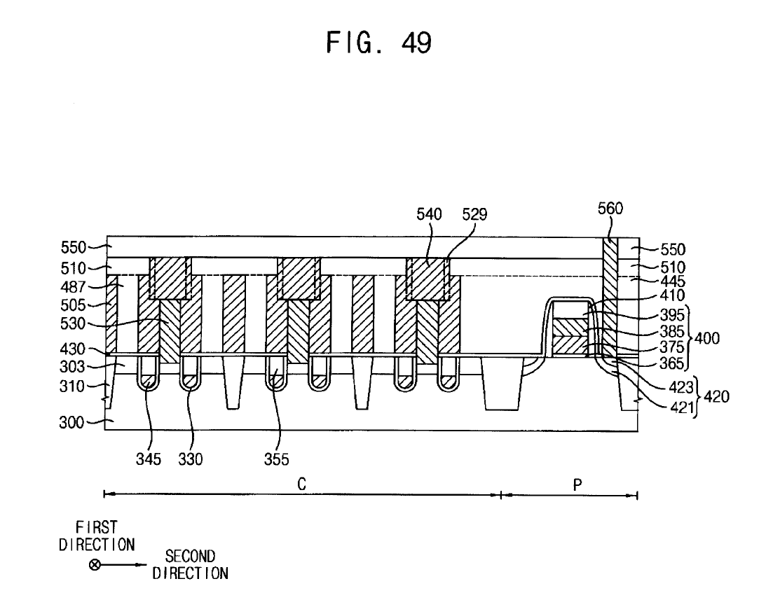

Referring to FIG. 49, a first contact plug 560 may be formed to fill the first contact hole 449.

The first contact plug 560 may be formed by forming a second conductive layer on the substrate 300 and the fifth mask 555 in the peripheral region P to fill the first contact hole 449, and planarizing the second conductive layer until a top surface of the fourth mask 550 may be exposed. Accordingly, the fifth mask 555 may be removed, and the first contact plug 560 may be formed to contact the exposed portion of the top surface of the impurity regions 420. In some embodiments, when the second transistor is a high voltage transistor, the first contact plug 560 may be formed to contact the third impurity region 423 having a relatively higher impurity concentration, and when the second transistor is a low voltage transistor, the first contact plug 560 may be formed to contact the second impurity region 421 having a relatively lower impurity concentration. The second conductive layer may be formed to include a metal and/or polysilicon doped with impurities.

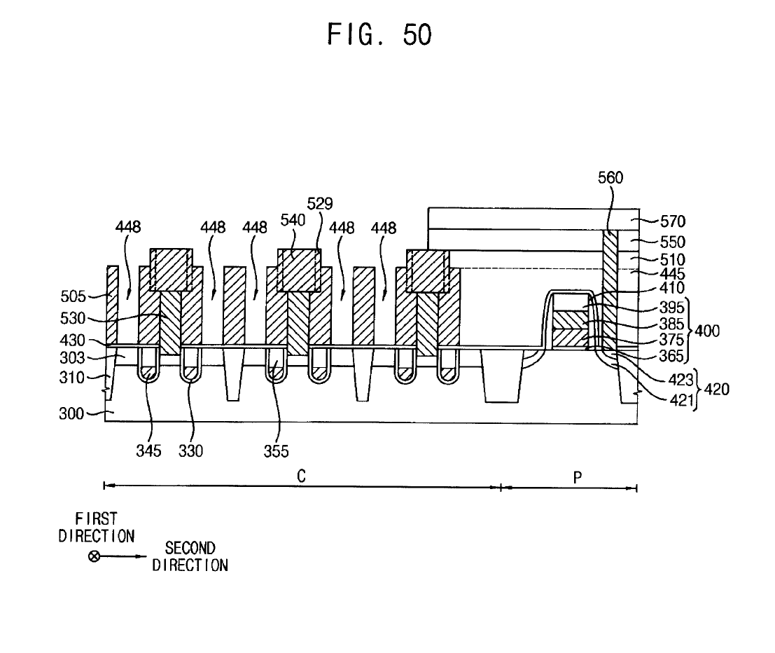

Referring to FIG. 50, a third photoresist pattern 570 may be formed on the third patterns and the fourth mask 550, and the second capping layer 510 and the second patterns 487 thereunder may be etched using the third photoresist pattern 570 as an etching mask.

The third photoresist pattern 570 may be formed to cover the peripheral region P and a portion of the cell region C adjacent thereto. Accordingly, a first insulating interlayer pattern 445 in the peripheral region P may be protected during the etching process.

In some embodiments, the second capping layer 510 and the second patterns 487 may include a material having an etching selectivity with respect to the first patterns 505, the third patterns, the fourth capping layer patterns 540 and the etch stop layer patterns 529, e.g., an oxide such as silicon oxide, and thus may be removed by performing a wet etching process.

Thereafter, the exposed portions of the etch stop layer 430 in the cell region C may be removed by, for example, a dry etching process to form ninth openings 448 exposing portions of the top surface of the substrate 300.

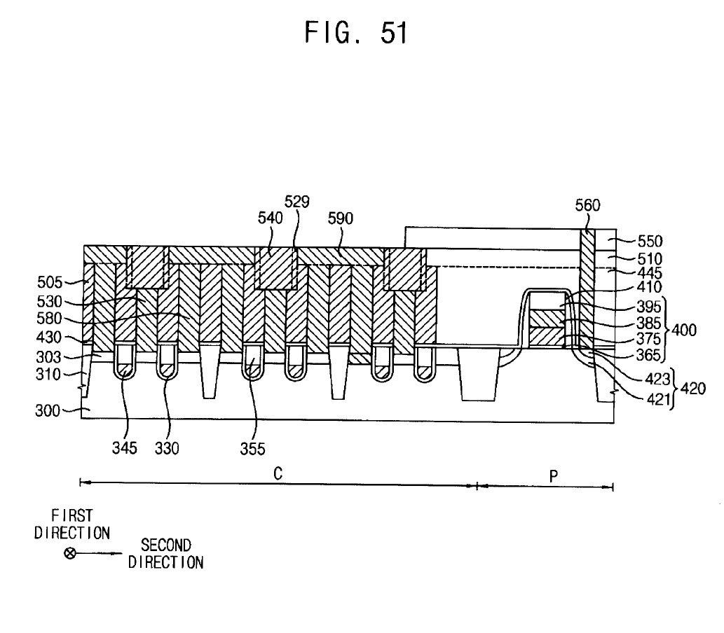

Referring to FIG. 51, a second contact plug 580 and a pad layer 590 may be formed to fill each ninth opening 448.

The second contact plug 580 and the pad layer 590 may be formed by forming a third conductive layer on the substrate 300, the first patterns 505, the third patterns, the fourth capping layer pattern 540, the etch stop layer pattern 529 and the fourth mask 550 to fill the ninth openings 448, and planarizing an upper portion of the third conductive layer until the top surface of the fourth capping layer pattern 540 may be exposed. Upper portions of the planarized third conductive layer may serve as pad layer 590, and lower portions of the planarized third conductive layer may serve as the second contact plug 580. That is, the second contact plug 580 and the pad layer 590 may be formed to include substantially the same material by a single process, and thus may be formed in a self-aligned manner. In addition, the second contact plug 580 and the pad layer 590 may not be formed by separate processes, which may reduce the etching process for forming fine patterns. The third conductive layer may include a metal and/or polysilicon doped with impurities.

A plurality of second contact plugs 580 may be formed both in the first and second directions, and each second contact plug 580 may be formed to contact the first impurity region 303 in the cell region C. In example embodiments, a top surface of the pad layers 590 may be substantially coplanar with those of the third patterns, the fourth capping layer patterns 540, the etch stop layer patterns 529.

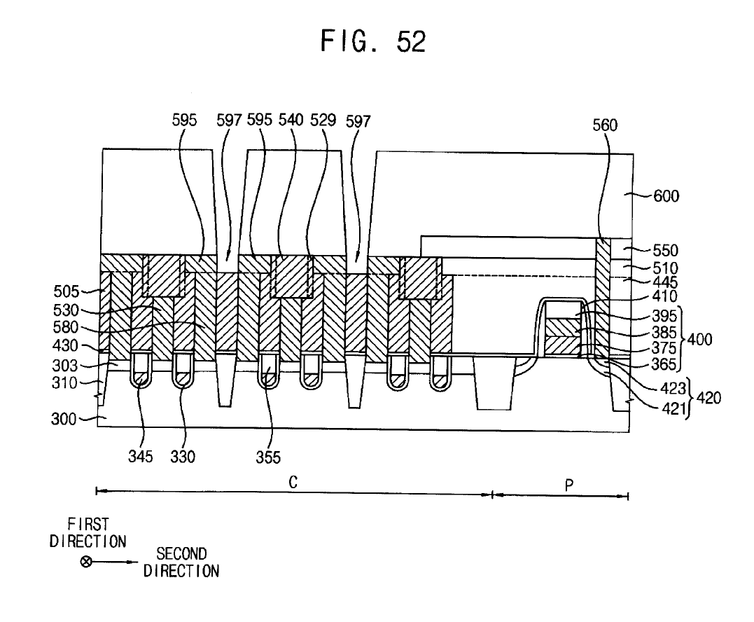

Referring to FIG. 52, a sixth mask 600 may be formed on the pad layers 590, the fourth capping layer patterns 540, the etch stop layer patterns 529 and the fourth mask 550 in the cell region C and the peripheral region P, and the pad layers 590 may be etched using the sixth mask 600 as an etching mask. Thus, the pads 595 separated by a tenth opening 597 may be formed.

In example embodiments, the sixth mask 600 may expose portions of the pad layer 590 on the first patterns 505 in the cell region C, and may cover the entire portion of the peripheral region P. Thus, each pad layer 590 may be divided into two pads 595 by the etching process, and the tenth openings 597 may expose portions of a top surface of the first patterns 505. A width of each pad 595 in the second direction may be larger than that of each second contact plug 580.

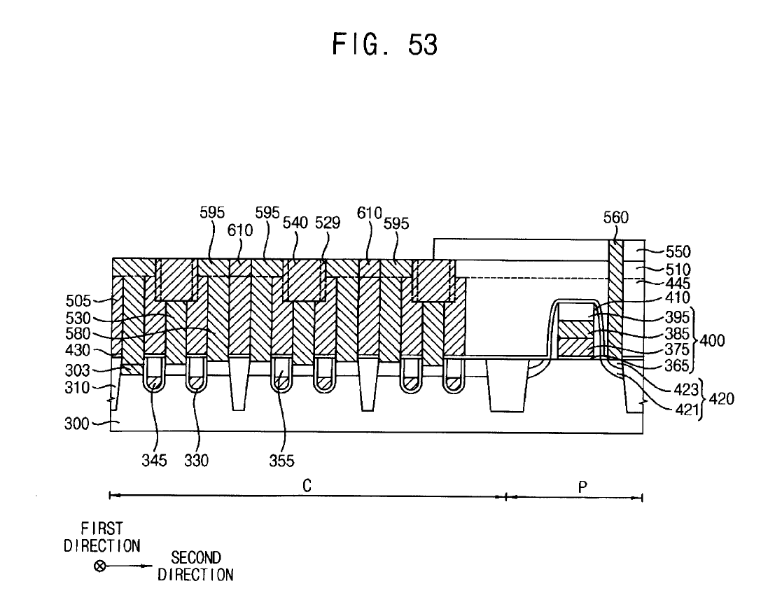

Referring to FIG. 53, a division layer pattern 610 may be formed to fill each tenth opening 597.

The division layer pattern 610 may be formed by removing the sixth mask 600, forming an insulating layer on the third patterns, the pads 595, the fourth capping layer patterns 540, the etch stop layer patterns 529 and the fourth mask 550 in the cell region C to fill the tenth opening 597, and planarizing an upper portion of the insulating layer until a top surface of the pads 595 may be exposed. The insulating layer may be formed to include a nitride, e.g., silicon nitride.

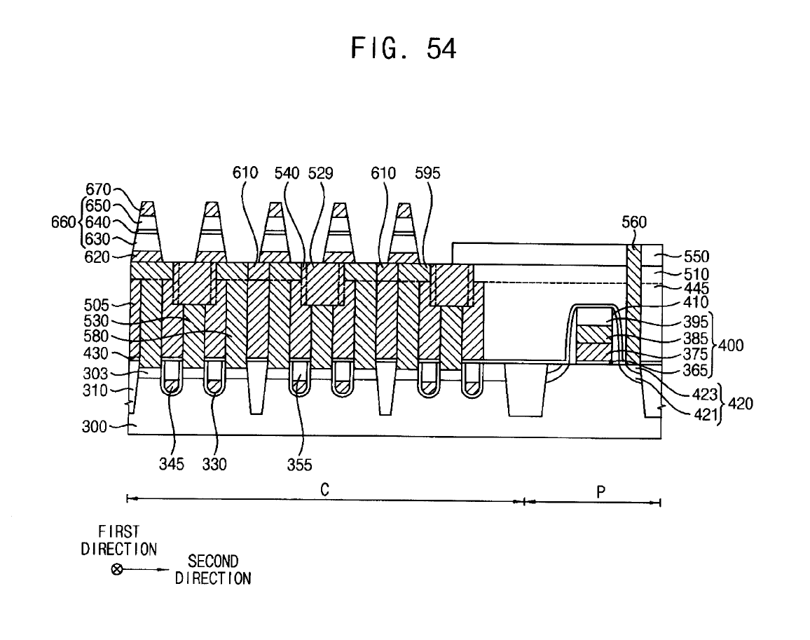

Referring to FIG. 54, a lower electrode 620, a magnetic tunnel junction (MTJ) structure 660 and an upper electrode 670 sequentially stacked on each pad 595 may be formed. In an example embodiment, the MTJ structure may include a fixed layer structure pattern 630, a tunnel barrier layer pattern 640 and a free layer pattern 650 sequentially stacked.

The lower electrode 620, the MTJ structure 660 and the upper electrode 670 may be formed by sequentially forming a lower electrode layer, a fixed layer structure, a tunnel barrier layer, a free layer and a upper electrode layer on the pads 595, the division layer pattern 610, the fourth capping layer patterns 540, the etch stop layer patterns 529 and the fourth mask 550 in the cell region C, etching the upper electrode layer to form the upper electrode 670, and patterning the free layer, the tunnel barrier layer, the fixed layer structure and the lower electrode layer by a dry etching process using the upper electrode 670 as an etching mask.

The lower and upper electrode layers may be formed to include a metal and/or a metal nitride.

A barrier layer (not shown) may be further formed on the lower electrode layer to prevent a metal of the fixed layer structure from growing abnormally. The barrier layer may be formed to include an amorphous metal or a metal nitride, e.g., tantalum, tantalum nitride, titanium, titanium nitride, etc.

In an example embodiment, the fixed layer structure may include a pinning layer, a lower ferromagnetic layer, anti-ferromagnetic coupling spacer layer and an upper ferromagnetic layer. The pinning layer may be formed to include, e.g., FeMn, IrMn, PtMn, MnO, MnS, MnTe, MnF₂, FeF₂, FeCl₂, FeO, CoCl₂, CoO, NiCl₂, NiO, Cr, etc. The lower and upper ferromagnetic layers may be formed to include, e.g., Fe, Ni, Co, etc. The anti-ferromagnetic coupling spacer layer may be formed to include, e.g., Ru, Ir, Rh, etc.

In some other embodiments, the fixed layer may not need to include a pinning layer.

The tunnel barrier layer may be formed to include, e.g., aluminum oxide or magnesium oxide. The free layer may be formed to include, e.g., Fe, Ni, Co, etc.

The MTJ structure 660 and the process for forming the MTJ structure 430 may not be limited to the above description. Although it is not specifically illustrated, various types of MTJ patterns may be formed. For example, multiple pinned layers may be formed with a free magnetic layer pattern therebetween to form, for example, double MTJ structure. In addition, the present disclosure may be applied to other types of memory devices.

When the dry etching process is performed, a conductive polymer may be attached to sidewalls of the MTJ structures 660, and thus the fixed layer structure pattern 630 and the free layer pattern 650 can be electrically short. In order to prevent the electrical short, the MTJ structures 660 may be formed to be spaced apart from each other. In some embodiments, the MTJ structures 660 may be formed at vertices and centers of hexagons in a top view.

Each MTJ structure 660 may contact each pad 595 through the lower electrode 620, and may be electrically connected to the first impurity region 303 of the substrate 300. A plurality of the MTJ structure 660 may be formed in the first and second direction, and one MTJ structure 660 may be formed to overlap one pad 595.

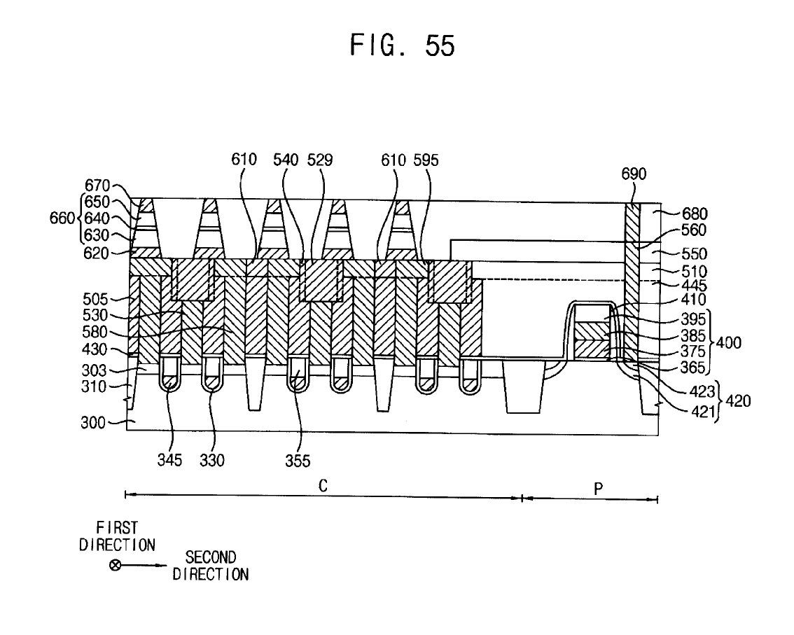

Referring to FIG. 55, a second insulating interlayer 680 may be formed in the cell region C and the peripheral region P to cover the lower electrode 620, the MTJ structure 660 and the upper electrode 670. A third contact plug 690 may be formed though the second insulating interlayer 680 in the peripheral region P.

The second insulating interlayer 680 may be formed to include an oxide, e.g., boro phospho silicate glass (BPSG), undoped silicate glass (USG) and spin on glass (SOG), etc.

A seventh mask (not shown) exposing a portion of the peripheral region P may be formed on the second insulating interlayer 680, the second insulating interlayer 680 may be etched using the seventh mask as an etching mask to form a second contact hole (not shown), and a fourth conductive layer pattern filling the second contact hole may be formed to form the third contact plug 690. According to the etching process, the second contact hole may expose a top surface of the first contact plug 560, and thus the third contact plug 690 may be formed to contact the first contact plug 560. The third contact plug 690 and the second transistor may be electrically connected. The fourth conductive layer pattern may be formed to include a metal and/or polysilicon doped with impurities.

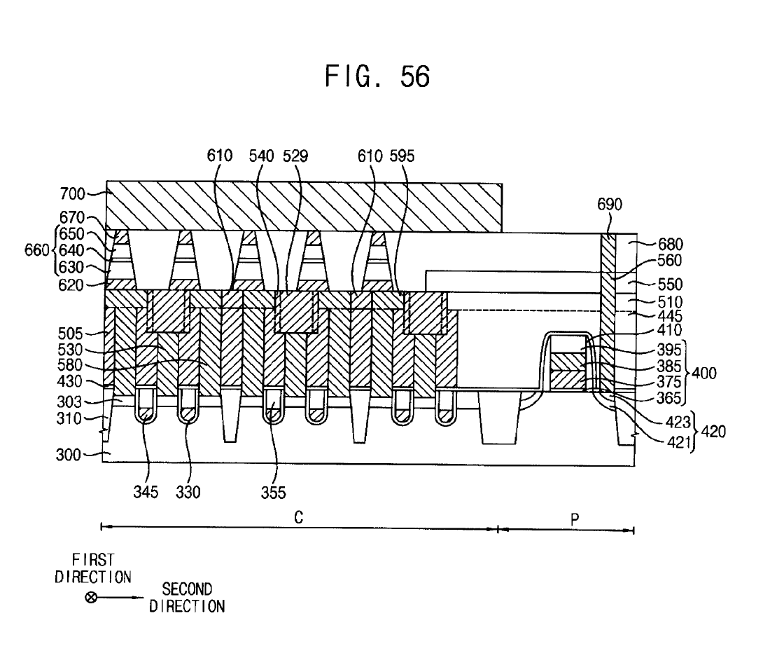

Referring to FIG. 56, a bit line 700 may be formed on the second insulating interlayer 680 in the cell region C.

The bit line 700 may be formed to contact the upper electrode 670. The bit line 700 may extend in the second direction, and a plurality of the bit line 700 may be formed in the first direction. The bit line 700 may be formed to include a conductive material such as metal, a metal nitride and/or a metal silicide.

Thereafter, a wire (not shown) may be formed on the second insulating interlayer 680 in the peripheral region P to contact the third contact plug 690 and the bit line 700. Accordingly, the cell region C and the peripheral region P may be electrically connected to manufacture the semiconductor device.

As described above, the second transistor may be formed only at the middle portion of the active region 307 in the first direction in the peripheral region P, and thus a hump phenomenon and/or HEIP may not be generated in the second transistor. As a result, electrical characteristics of the semiconductor device may be deteriorated, so that data stored in the cell region C may be accurately read though the peripheral region P.

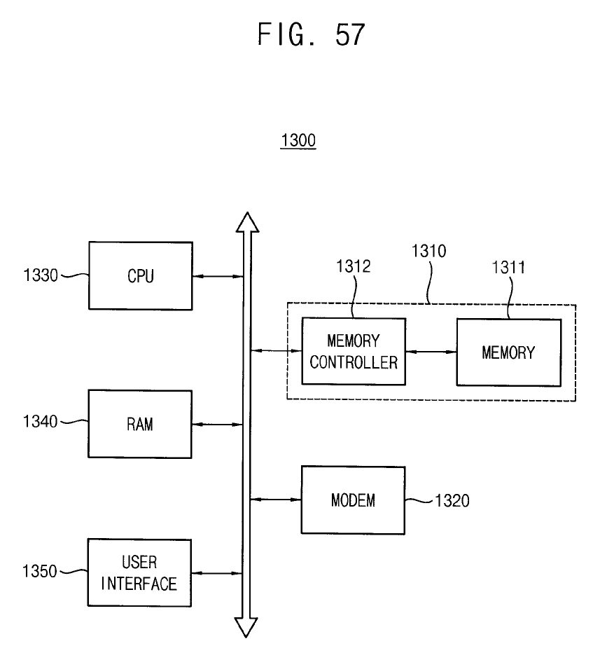

FIG. 57 is a schematic block diagram illustrating an example of information processing systems including a semiconductor device according to example embodiments of the present disclosure.

Referring to FIG. 57, an information processing system 1300 includes a memory system 1310, which may include at least one of the semiconductor devices according to example embodiments of the inventive concept. The information processing system 1300 may also include a modem 1320, a central processing unit (CPU) 1330, a RAM 1340, and a user interface 1350, which may be electrically connected to the memory system 1310 via a system bus 1360. The memory system 1310 may include a memory device 1311 and a memory controller 1312 controlling an overall operation of the memory device 1311. Data processed by the CPU 1330 and/or input from the outside may be stored in the memory system 1310. Here, the memory system 1310 may constitute a solid state drive SSD, and thus, the information processing system 1300 may be able to store reliably a large amount of data in the memory system 1310. Although not shown in the drawing, it will be apparent to those of ordinary skill in the art that the information processing system 1300 may be also configured to include an application chipset, a camera image processor (CIS), and/or an input/output device.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A transistor, comprising:
a substrate divided into a field region and an active region by an isolation layer pattern, the field region having the isolation layer pattern thereon, and the active region having substantially no isolation layer pattern thereon;
a gate structure including a central portion and an edge portion, the central portion being on a middle portion of the active region along a first direction and having a first width in a second direction substantially perpendicular to the first direction, the edge portion being on at least one end portion of the active region in the first direction and connected to the central portion and having a second width smaller than the first width in the second direction; and
impurity regions at upper portions of the active region adjacent to both end portions of the gate structure in the second direction.

2. A transistor of claim 1, wherein the edge portion of the gate structure is formed on both end portions of the active region in the first direction.

3. A transistor of claim 1, wherein the edge portion of the gate structure is formed on a portion of the isolation layer pattern adjacent to the at least one end portion of the active region in the first direction.

4. A transistor of claim 1, wherein each impurity region extends in the first direction in the active region.

5. A transistor of claim 4, wherein each impurity region extends in the first direction with a substantially uniform width in the second direction.

6. A transistor of claim 1, wherein each impurity region includes a first impurity region having a first impurity concentration and a second impurity region having a second impurity concentration higher than the first impurity concentration.

7. A transistor of claim 6, wherein the second impurity region is formed within the first impurity region in plan view.

8. A method of manufacturing a transistor, the method comprising:
forming an isolation layer pattern on the substrate to divide the substrate into an active region and a field region;
forming a gate structure to include a central portion and an edge portion, the central portion being on a middle portion of the active region along a first direction and having a first width in a second direction substantially perpendicular to the first direction, the edge portion being on at least one end portion of the active region in the first direction and connected to the central portion and having a second width smaller than the first width in the second direction; and
forming impurity regions at upper portions of the active region adjacent to both end portions of the gate structure in the second direction.

9. The method of claim 8, wherein forming the impurity regions includes:
performing an ion implantation process using an ion implantation mask having openings, each of the openings extending in the first direction adjacent to the end portions of the gate structure in the second direction.

10. The method of claim 8, wherein forming the impurity regions includes:
performing an ion implantation process using an ion implantation mask, the ion implantation mask having a width equal to or greater than the first width of the gate structure in the second direction and covering the edge portion of the gate structure and a portion of the active region adjacent thereto.

11. The method of claim 8, wherein the edge portion of the gate structure is formed on both end portions of the active region in the first direction.

12. The method of claim 8, wherein the edge portion of the gate structure is formed on a portion of the isolation layer pattern adjacent to the at least one end portion of the active region in the first direction.

13. The method of claim 8, wherein each impurity region is formed to extend in the first direction with a substantially uniform width in the second direction in the active region.

14. The method of claim 8, wherein each impurity region is formed to include a first impurity region having a first impurity concentration and a second impurity region having a second impurity concentration higher than the first impurity concentration.

15. The method of claim 8, wherein forming the gate structure includes:
sequentially forming a gate insulation layer, a gate electrode layer and a mask on the substrate and the isolation layer pattern; and
sequentially patterning the gate electrode layer and the gate insulation layer using the mask as an etching mask.

16. A device, comprising:
a substrate having an isolation layer pattern defining an active region and a field region;
a gate structure for forming a transistor, the gate structure including a central portion, the central portion being arranged substantially entirely on a middle portion of the active region such that a channel of the transistor is not formed at an interface between the active region and the field region; and
impurity regions adjacent to the gate structure.

17. The device of claim 16, wherein the gate structure further comprises an edge portion disposed on at least one end portion of the active region in the first direction and connected to the central portion and having a second width smaller than the first width in the second direction.

18. The device of claim 17, wherein the edge portion of the gate structure is formed on both end portions of the active region.

19. The device of claim 16, further comprising a MTJ structure overlying the substrate and connected to the transistor.

20. The device of claim 16, wherein a sidewall of the gate structure is substantially covered by a spacer, wherein the spacer is formed only on the middle portion of the active region and is not formed on the field region.

21. The device of claim 16, wherein a sidewall of the gate structure is substantially covered by a spacer, the spacer is formed on both end portions of the active region.

22. The device of claim 16, wherein the substrate includes a cell region and a peripheral region, the gate structure is formed on the peripheral region.
